(19) United States
(12) Patent Application Publication
(10) Pub. No.: US 2026/0261149 A1
(43) Pub. Date: Sep. 3, 2026

(54) POWERING SYSTEM AND METHOD FOR POWERING DEVICES UTILIZING HUMAN WHOLE-BODY POWERING (HWBP) VIA CAPACITIVE ELECTRO-QUASISTATIC FIELDS

(71) Applicant: Quasistatics Inc., West Lafayette, IN (US)

(72) Inventors: Shreyas Sen, West Lafayette, IN (US); Lingke Ding, Lafayette, IN (US); Arunashish Datta, West Lafayette, IN (US)

(21) Appl. No.: 19/066,474

(22) Filed: Feb. 28, 2025

(51) Int. Cl. H02J 50/05; H03H 7/06; H03H 7/38

(52) U.S. Cl. CPC H02J 50/05; H03H 7/06; H03H 7/383

(57) ABSTRACT

A powering system and method for powering devices utilizing Human Whole-Body Powering (HWBP) via capacitive electro-quasistatic fields is disclosed. The system includes a transmitter configured to transmit electro quasistatic signals to a receiver via a human body channel using an electrostatic coupling. The electro quasistatic signals power the receiver. The human body electrically connected to the transmitter, and the human body channel is configured to transfer the electro quasistatic signals from the transmitter to the receiver. The human body channel comprises a body impedance value, a capacitive coupling, a contact impedance. Further, the receiver electrically connected to the human body channel, and the receiver is configured to deliver power to an electrical load of the receiver based on a powering level.

### TECHNICAL FIELD

Embodiments of the present disclosure generally relate to powering systems, and more particularly relates to a powering system and method for powering devices utilizing Human Whole-Body Powering (HWBP) via capacitive electro-quasistatic fields.

### BACKGROUND

Advancing human-machine symbiosis is a primary objective in the ongoing technological revolution, encompassing various research fields, including advanced artificial intelligence models and the development of more sophisticated wearable devices. This has led to the emergence of the Internet of Bodies (IoB), which provides a low-latency, high-bandwidth, and low-energy network on and around the human body. However, a significant challenge remains in powering on-body devices, which traditionally rely on batteries that require frequent recharging, disrupting continuous use and becoming burdensome as the number of devices increases. While low-power communication techniques, such as Human-Body Communication (HBC), may reduce charging frequency, there is still a need for efficient energy harvesting and wireless power transfer methods.

Currently, capacitive HBC is utilized for wireless power transfer in the Megahertz (MHz) range, with two distinct operational modes segregated around 30 MHz. Below this frequency, the human body functions as a highly inefficient antenna, where the Electro-Quasistatic (EQS) range facilitates efficient power transfer by confining signals within the body and simplifying operational complexity. Despite extensive research on EQS-HBC, there is a significant lack of thorough analysis on electro-quasistatic human body powering (EQS-HBP) to inform future developments.

While conventional systems address aspects of human-body communication (HBC) and electro-quasistatic human-body powering (EQS-HBP), the conventional systems include limitations in providing efficient, continuous, and comprehensive power transfer across the human body. Conventional systems lack an integrated solution that optimizes both energy transfer efficiency and full-body coverage. Furthermore, there is insufficient exploration of the distinct operational characteristics between EQS-HBC and EQS-HBP, particularly in achieving effective impedance matching and ensuring reliable power delivery for diverse wearable applications.

Therefore, there is a need in the art to provide a powering system and method for powering devices utilizing Human whole-Body Powering (HWBP) via capacitive electro-quasistatic fields, by optimizing impedance matching, enhancing power transfer efficiency, and ensuring comprehensive full-body coverage, enabling seamless operation of on-body devices without frequent recharging, and to address the aforementioned deficiencies in the art.

### SUMMARY

This summary is provided to introduce a selection of concepts, in a simple manner, which is further described in the detailed description of the disclosure. This summary is neither intended to identify key or essential inventive concepts of the subject matter nor to determine the scope of the disclosure.

An aspect of the present disclosure provides a powering system for powering devices utilizing Human Whole-Body Powering (HWBP) via capacitive electro-quasistatic fields. The system includes a transmitter configured to transmit electro quasistatic signals to a receiver via a human body channel using an electrostatic coupling. The electro quasistatic signals power the receiver. Further, the human body is electrically connected to the transmitter. The human body channel is configured to transfer the electro quasistatic signals from the transmitter to the receiver. The human body channel comprises a body impedance value, a capacitive coupling, a contact impedance. Furthermore, the system includes the receiver electrically connected to the human body channel. The receiver is configured to deliver power to an electrical load of the receiver based on a powering level.

Another aspect of the present disclosure includes a method for powering devices utilizing Human Whole-Body Powering (HWBP) via capacitive electro-quasistatic fields. The method includes transmitting electro-quasistatic signals to a receiver via a human body channel using electrostatic coupling. The electro-quasistatic signals power the receiver. The human body channel includes a body impedance value, a capacitive coupling, and a contact impedance. Human body channel is configured to transfer the electro-quasistatic signals from the transmitter to the receiver. Furthermore, the method includes receiving the electro-quasistatic signals via a signal electrode electrically coupled to the human body channel. Additionally, the method includes inducing a differential alternating current voltage across the signal electrode and a receiver ground electrode of the receiver in response to the received electro-quasistatic signals. The differential alternating current voltage includes a frequency corresponding to a frequency of the electro-quasistatic signals and an amplitude dependent on a grounding configuration of the transmitter and the receiver. Further, the method includes delivering power to an electrical load of the receiver based on the induced differential alternating current voltage.

To further clarify the advantages and features of the present disclosure, a more particular description of the disclosure will follow by reference to specific embodiments thereof, which are illustrated in the appended figures. It is to be appreciated that these figures depict only typical embodiments of the disclosure and are therefore not to be considered limiting in scope. The disclosure will be described and explained with additional specificity and detail with the appended figures.

### BRIEF DESCRIPTION OF ACCOMPANYING DRAWINGS

The disclosure will be described and explained with additional specificity and detail with the accompanying figures in which:

FIGS. 1A-B are example block diagram representations of an exemplary powering system for capacitive Electro-Quasi Static Human Body Powering (EQS-HBP) using a Human Body Communication (HBC) network, in accordance with an embodiment of the present disclosure;

FIG. 2 is an example block diagram representation of a powering system, such as those shown in FIG. 1, for transferring power to another device using capacitive Electro-Quasi Static Human Body Powering (EQS-HBP), in accordance with an embodiment of the present disclosure;

FIG. 3A illustrates schematic representations of a plurality of example ground electrode configurations of a transmitter and a receiver, in accordance with an embodiment of the present disclosure;

FIG. 3B illustrates a circuit diagram of a capacitive Electro-Quasi Static Human Body Powering (EQS-HBP) using a Human Body Communication (HBC) network, in accordance with an embodiment of the present disclosure;

FIG. 3C illustrates a circuit diagram for termination impedance options, in accordance with an embodiment of the present disclosure;

FIG. 3D illustrates a circuit diagram for ground-connected receiver with high impedance termination boosts channel capacity, in accordance with an embodiment of the present disclosure;

FIG. 3E illustrates a circuit diagram for ground-floated receiver with high impedance termination boosting Signal-to-Noise Ratio (SNR), in accordance with an embodiment of the present disclosure;

FIG. 4A illustrates schematic representations of generating a distributed resistor-capacitor (RC) circuit from pre-defined dimensions of a skin block and a muscle block, by dividing it into smaller unit blocks and combining the unit blocks into a circuit, in accordance with an embodiment of the present disclosure;

FIG. 4B illustrates a schematic representation of a Finite Element Modeling (FEM) of a body model for a skin block and a muscle block, in accordance with an embodiment of the present disclosure;

FIG. 4C illustrates a circuit diagram representation of a distributed circuit model after combing smaller unit blocks, in accordance with an embodiment of the present disclosure;

FIG. 5A illustrates graph diagram representations of an on-body voltage distribution in a distributed circuit, and a lumped circuit models for a pre-defined load, where Electro-Quasistatic Human-Body Communication (EQS-HBC) body as equipotential surface, in accordance with an embodiment of the present disclosure;

FIG. 5B illustrates graph diagram representations of comparison between result of simulation associated with a lumped circuit and a distributed circuit, where the resistance load is in kilo ohms (Ω), in accordance with an embodiment of the present disclosure;

FIG. 5C illustrates graph diagram representations of an on-body voltage distribution in a distributed circuit, and a lumped circuit models for a pre-defined load, for on-body voltage changes, in accordance with an embodiment of the present disclosure;

FIG. 5D illustrates graph diagram representations of comparison between result of simulation associated with a lumped circuit and a distributed circuit, where the resistance load is in ohms (Ω), in accordance with an embodiment of the present disclosure;

FIG. 5E illustrates graph diagram representations of on-body voltage distribution prediction by comparison of on-body voltage predictions across various on-body vertical locations and R_{load}, in accordance with an embodiment of the present disclosure;

FIG. 5F illustrates graph diagram representations of effect of height on R_{body} and Pᵣₓ for a constant cross-sectional area, in accordance with an embodiment of the present disclosure;

FIG. 5G illustrates a circuit diagram representation of a lumped circuit model with R_{body}, in accordance with an embodiment of the present disclosure;

FIG. 6 illustrates heatmap representations of impact of contact area along with comparison of contact impedance and contact area, in accordance with an embodiment of the present disclosure;

FIG. 7 illustrates a circuit diagram for a transmitter and a receiver in a capacitive Electro-Quasi Static Human Body Powering (EQS-HBP), according to an example embodiment of the present disclosure;

FIG. 8A illustrates a graph representation of variation of on-body voltage across vertical locations for R_{load} with three different contact areas, according to an example embodiment of the present disclosure;

FIG. 8B illustrates heat map representations of variation of on-body voltage vertical locations for R_{load} with three different contact areas with V_{load} across R_{load}, according to an example embodiment of the present disclosure;

FIG. 8C illustrates a graph diagram for inclusion of Z_{contact} matches distributed circuit to simulation results, according to an example embodiment of the present disclosure;

FIG. 8D illustrates a graph diagram for V_{load} variation against R_{load} across the three contact sizes, according to an example embodiment of the present disclosure;

FIG. 8E illustrates a graph diagram for change in Z_{contact} with respect to contact area at Megahertz (MHz) range, according to an example embodiment of the present disclosure;

FIG. 9 illustrates a circuit diagram for a final lumped circuit model for capacitive EQS-HBP, where the body channel is represented as a uniformly distributed finite-impedance wire with an additional contact impedance, Z_{contact}, according to an example embodiment of the present disclosure;

FIG. 10A illustrates a graph diagram for an impact of contact impedance on Pᵣₓ, according to an example embodiment of the present disclosure;

FIG. 10B illustrates a schematic diagram of simulation results torso cross-sectional areas without limb, according to an example embodiment of the present disclosure;

FIG. 10C illustrates a schematic diagram of simulation results torso cross-sectional areas with limb, according to an example embodiment of the present disclosure;

FIG. 10D illustrates a graph diagram of results of a simulation of a three different torso cross-sectional areas were simulated, according to an example embodiment of the present disclosure;

FIG. 10E illustrates a graph diagram of a results of a simulation of a three different torso cross-sectional areas with arm, according to an example embodiment of the present disclosure;

FIG. 10F illustrates a graph diagram of a V_{body} along the torso with cross-sectional area evaluated against changes in R_{load}, according to an example embodiment of the present disclosure;

FIG. 10G illustrates a graph diagram of simulation results for a model with varying the cross-sectional area of the limb (arm) while keeping the torso cross-sectional area constant, according to an example embodiment of the present disclosure;

FIGS. 11A-D illustrate circuit diagrams of four configurations of capacitive EQS-HBP, according to an example embodiment of the present disclosure;

FIG. 11E illustrates a circuit diagram for primary parasitic capacitors Cₚₚ and Cᵣₑₜ, according to an example embodiment of the present disclosure;

FIGS. 11F and 11G illustrate circuit diagrams for parallel resonance and series resonance, respectively, according to an example embodiment of the present disclosure;

FIG. 12A illustrates a graph diagram of an optimal Rload that maximizes Prx across two scenarios such as perfect and imperfect frequency alignment between TX and RX series resonance frequency, according to an example embodiment of the present disclosure;

FIG. 12B illustrates a graph diagram of an optimal Rload that maximizes Prx across different return path impedance, covering from ground-connected RX to ground-floated RX, according to an example embodiment of the present disclosure; and

FIG. 13 illustrates an exemplary flow chart depicting a method for powering devices utilizing Human Whole-Body Powering (HWBP) via capacitive electro-quasistatic fields, according to an example embodiment of the present disclosure.

Further, those skilled in the art will appreciate that elements in the figures are illustrated for simplicity and may not have necessarily been drawn to scale. Furthermore, in terms of the construction of the device, one or more components of the device may have been represented in the figures by conventional symbols, and the figures may show only those specific details that are pertinent to understanding the embodiments of the present disclosure so as not to obscure the figures with details that will be readily apparent to those skilled in the art having the benefit of the description herein.

### DETAILED DESCRIPTION

For simplicity and illustrative purposes, the present disclosure is described by referring mainly to examples thereof. The examples of the present disclosure described herein may be used together in different combinations. In the following description, details are set forth in order to provide an understanding of the present disclosure. It will be readily apparent, however, that the present disclosure may be practiced without limitation to all these details. Also, throughout the present disclosure, the terms “a” and “an” are intended to denote at least one of a particular element. The terms “a” and “an” may also denote more than one of a particular element. As used herein, the term “includes” means includes but not limited to, the term “including” means including but not limited to. The term “based on” means based at least in part on, the term “based upon” means based at least in part upon, and the term “such as” means such as but not limited to. The term “relevant” means closely connected or appropriate to what is being performed or considered.

For the purpose of promoting an understanding of the principles of the disclosure, reference will now be made to the embodiment illustrated in the figures and specific language will be used to describe them. It will nevertheless be understood that no limitation of the scope of the disclosure is thereby intended. Such alterations and further modifications in the illustrated system, and such further applications of the principles of the disclosure as would normally occur to those skilled in the art are to be construed as being within the scope of the present disclosure. It will be understood by those skilled in the art that the foregoing general description and the following detailed description are exemplary and explanatory of the disclosure and are not intended to be restrictive thereof.

In the present document, the word “exemplary” is used herein to mean “serving as an example, instance, or illustration”. Any embodiment or implementation of the present subject matter described herein as “exemplary” is not necessarily to be construed as preferred or advantageous over other embodiments. The terms “comprise”, “comprising”, or any other variations thereof, are intended to cover a non-exclusive inclusion, such that one or more devices or sub-systems or elements or structures or components preceded by “comprises . . . a” does not, without more constraints, preclude the existence of other devices, sub-systems, additional sub-modules. Appearances of the phrase “in an embodiment”, “in another embodiment”, “in an exemplary embodiment” and similar language throughout this specification may, but not necessarily do, all refer to the same embodiment.

Unless otherwise defined, all technical and scientific terms used herein have the same meaning as commonly understood by those skilled in the art to which this disclosure belongs. The system, methods, and examples provided herein are only illustrative and not intended to be limiting. A computer system (standalone, client, or server, or computer-implemented system) configured by an application may constitute a “module” (or “subsystem”) that is configured and operated to perform certain operations. In one embodiment, the “module” or “subsystem” may be implemented mechanically or electronically, so a module includes dedicated circuitry or logic that is permanently configured (within a special-purpose processor) to perform certain operations. In another embodiment, a “module” or a “subsystem” may also comprise programmable logic or circuitry (as encompassed within a general-purpose processor or other programmable processor) that is temporarily configured by software to perform certain operations. Accordingly, the term “module” or “subsystem” should be understood to encompass a tangible entity, be that an entity that is physically constructed permanently configured (hardwired), or temporarily configured (programmed) to operate in a certain manner and/or to perform certain operations described herein.

Embodiments described herein provide a system and method for powering devices utilizing Human Whole-Body Power (HWBP) via capacitive electro-quasistatic fields. The system includes a transmitter configured to transmit electro quasistatic signals to a receiver via a human body channel using an electrostatic coupling. The electro quasistatic signals power the receiver. Further, the human body is electrically connected to the transmitter. The human body channel is configured to transfer the electro quasistatic signals from the transmitter to the receiver. The human body channel comprises a body impedance value, a capacitive coupling, a contact impedance. Furthermore, the system includes the receiver electrically connected to the human body channel. The receiver is configured to deliver power to an electrical load of the receiver based on a powering level.

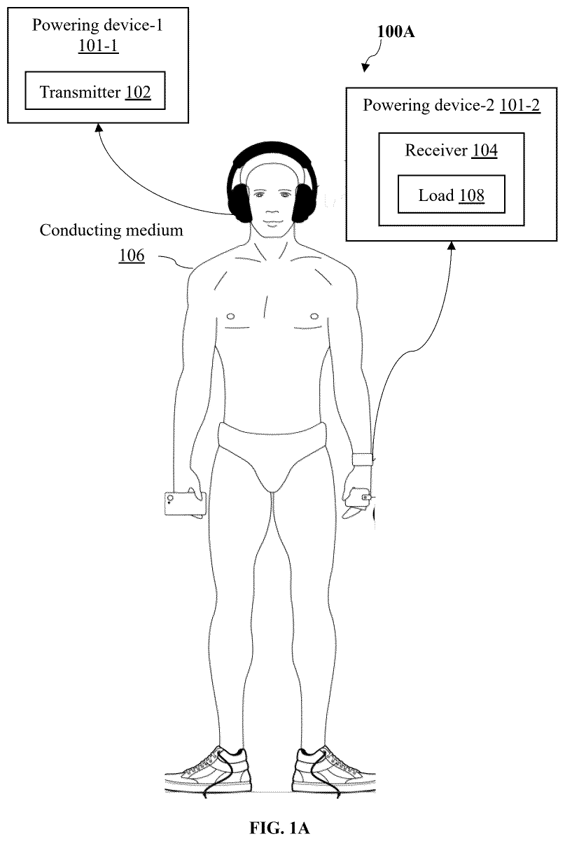

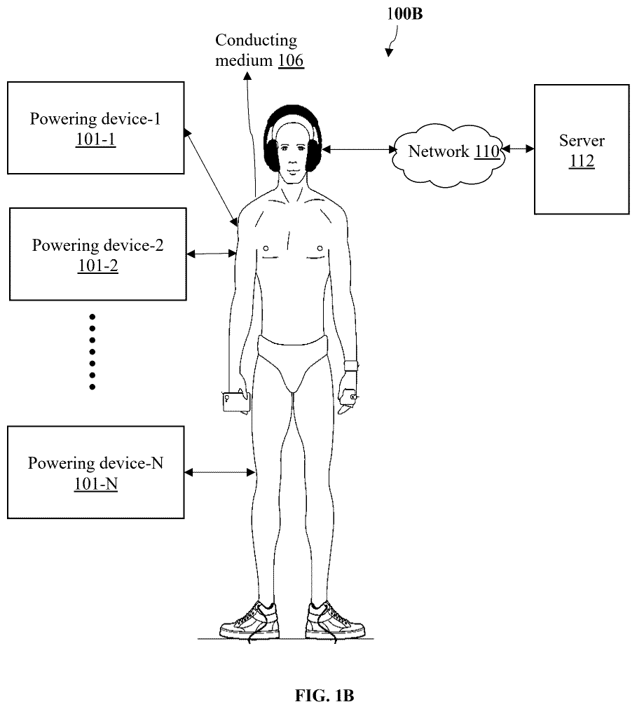

Referring now to the drawings, and more particularly to FIG. 1A through FIG. 13, where similar reference characters denote corresponding features consistently throughout the figures, there are shown preferred embodiments, and these embodiments are described in the context of the following exemplary system and/or method.

FIGS. 1A-B are example block diagram representations of an exemplary powering system 100A, 100B for capacitive Electro-Quasi Static Human Body Powering (EQS-HBP) using a Human Body Communication (HBC) network, in accordance with an embodiment of the present disclosure. In one example, the powering system 100A may include a powering device-1 101-1, a powering device-2 101-2, and a conducting medium 106. In another example, the powering system 100B may include the powering device-1 101-1, the powering device-2 101-2, . . . , a powering device-N 101-N (individually referred to as the powering device 101 and collectively referred to as the powering devices 101), the conducting medium 106, and a server 112 connected via a network 110. The powering device-1 101-1 in the powering system 100A may include a transmitter 102, and the powering device-2 101-2 in the powering system 100A may include a receiver 104 which includes a load 108. In another example, the powering device-1 101-1, the powering device-2 101-2, . . . , the powering device-N 101-N may include one or more transceivers (not shown in FIG. 1A-B).

In an embodiment, the powering system 100A, 100B may include the conducting medium 106 communicatively coupled to the powering device-1 101-1 via a body communication network (not shown in FIG. 1A-B). In one example embodiment, the conducting medium 106 may be a human body communication network. Further, the conducting medium 106 is configured to establish a powering channel between the powering device 101-1 and the powering device-2 101-2. In an embodiment, the powering system 100A, 100B may further include the powering device-2 101-2 communicatively coupled to the powering device-1 101-1 via the conducting medium 106. The powering device-2 101-2 may include the receiver 104 and the electrical load 108.

The powering devices 101 may be, for example, but not limited to, a headphone, a smart-watch, a wristband, a smart eyewear, any other wearable devices, holdable devices, touchable devices, and the like. The conducing medium 106 may be, but not limited to, a human body, a cross-cylindrical human body model, parallel plates, and the like.

The transmitter 102 may be, for example, a module/unit in a watch-based device or a pendant based device. The receiver may be, for example, a module/unit in a sensor device such as an Electrocardiogram (ECG) patch, glucose sensor patch or a headphone, and the like.

The transmitting source may be for example, but not limited to, a plurality of devices or modules capable of generating and transmitting signals, for example, signal generator. For example, the transmitting source may include a wireless communication module embedded within a smartphone, smartwatch, or fitness tracker, facilitating the transmission of health-related data. The transmitting source may also comprise a medical device such as an insulin pump, a pacemaker, or an implantable cardioverter-defibrillator (ICD), transmitting patient health metrics for monitoring purposes. Additionally, the transmitting source may be an environmental sensor, such as a temperature, humidity, or air quality sensor, providing real-time data to a central processing unit. Other examples include smart home devices like motion sensors, security cameras, or smart speakers transmitting status updates or alerts, as well as industrial monitoring equipment used for transmitting operational data from machinery or systems in manufacturing environments. Furthermore, the transmitting source may include wearable devices with Near-Field Communication (NFC) or Bluetooth Low Energy (BLE) capabilities, enabling short-range data transfer to compatible receivers.

Further, the load 108 may include, but not limited to, a unit or a module or an application which needs power.

In one example embodiment, the transmitter 102 configured to generate Electro-Quasi static (EQS) signals for powering the receiver 104. The transmitter 102 is further configured to couple the EQS signals to the conducting medium 106 for transmitting the EQS signals, using an Electro-Quasistatic Human Body Powering (HBP). The transmitter 102 may electrically connect to the conducting medium 106 and the conducting medium 106 transfers the EQS signals from the transmitter 102 to the receiver 104 using an electrostatic coupling technique.

In one example embodiment, the receiver 104 is electrically coupled to the conducting medium 106. The receiver 104 is configured to receive the EQS signals from the transmitter 102 through the conducting medium 106, via the electrostatic coupling technique. Further, the receiver 104 is configured to deliver power to the electrical load 108 associated with the receiver 104, using the received EQS signals.

In one example embodiment, to deliver the power to the electrical load 108 associated with the receiver 104, using the received EQS signals, the receiver 104 comprises a signal electrode electrically connected to the communicating medium 106 (also referred herein as conducting medium 106). The signal electrode is configured to receive the EQS signals from the transmitter 102, through the medium 106, where the received EQS signals corresponds to a primary voltage value induced by the EQS signals transmitted from the transmitter 102. Further, the receiver 104 comprises a ground electrode coupled to a ground terminal. The ground electrode is configured to receive a secondary voltage value induced by the EQS signals transmitted from the transmitter 102. The receiver 104 is configured to receive a differential voltage value between the signal electrode, and the ground electrode of the receiver 104, based on the primary voltage value and the secondary voltage value. The receiver 104 is further configured to deliver power to the electrical load 108 associated with the receiver 104, based on the received differential voltage value.

In an example embodiment, the receiver 104 is configured to produce a differential alternating current voltage across the received EQS signal and the ground electrode. The differential alternating current voltage corresponds to a frequency of the electro-quasistatic signals with a reduced amplitude. The amplitude is reduced based on the transmitter 102 and receiver 104 ground configurations.

Further, in an example embodiment, the series resonant frequency value of the transmitter 102 depends on size of a primary parasitic capacitor connected parallelly to the transmitter 102. To boost power level of the EQS signals received, the receiver 104, in the ground-floated configuration, comprises a capacitor (not shown) in series with the electrical load 108. Further, the receiver 104 includes at least one capacitor. The at least one capacitor comprises one of a parasitic capacitor Cₚₚ existing between the signal electrode and the ground electrode of the receiver 104, a return path parasitic capacitor (Cᵣₑₜ); and one or more additional capacitor in parallel with the parasitic capacitor Cₚₚ to adjust the resonant frequency. The series resonance boosts a voltage received by the electrical load 108 and the series resonance boosts the voltage received through cancellation of effect of the return path parasitic capacitor Cᵣₑₜ.

In an example embodiment, the transmitter 102 in the ground floated configuration, comprises at least one capacitor. The at least one capacitor comprises one of a parasitic capacitor Cₚₚ existing between the signal electrode and the ground electrode of the transmitter 102, and an additional capacitor in parallel with the parasitic capacitor Cₚₚ. Further, the series resonance boosts the voltage coupled onto the communication/conductive medium 106 to boost the power transmitted.

At the receiver 104, when the receiver 104 is in ground-floated configuration, the power received depends on a ratio of parasitic capacitor Cₚₚ to return path parasitic capacitor Cᵣₑₜ value, and on a specific magnitude value of the return path parasitic capacitor Cᵣₑₜ. The electro-quasistatic human body powering system uses the human body as a medium for a power transfer, minimizing electromagnetic radiation while enhancing signal containment and efficiency.

In an example, the transmitter 102 may generates, couple, and adjusts the electro-quasistatic signal, which can be a periodic signal in the form of either a square wave, a sine wave, and the like. The transmitter 102 may include, but not limited to, direct current to alternating current conversion (DC to AC), to generate the electro-quasistatic signal. The transmitter 102 may include one or more accessible external nodes, which include the ground electrode and the signal electrode. To enable power transfer, the transmitter signal electrode may be in contact with or in very close proximity (e.g., less than half a centimeter) to the human body. The electrode may exist in a plurality of forms and sizes, ranging from a bare jumper wire to a large metallic surface, and the like.

The ground electrode of the transmitter 102 may include two distinct configurations. In a first configuration, the transmitter ground electrode may be electrically connected to the environmental ground. This connection may be direct, such as a wire connected to a wall-mounted electrical outlet ground, or indirect, such as a metallic plate placed on a large object like a table, acting as a pseudo-ground. In a second configuration, the transmitter ground electrode may not be connected to the environmental ground. In this case, the transmitter 102 may include a mobile power source, such as a battery, and is lifted in the air with the ground electrode not in contact with any objects, including the human body.

The receiver 104 may be configured to receive power from the transmitter 102 through the body channel capacitively. Similar to the transmitter 102, the receiver 104 may include a signal electrode and a ground electrode. To enable power reception, the receiver signal electrode may be in contact with or in very close proximity (e.g., less than half a centimeter) to the human body. The receiver ground electrode may include two configurations. In a first configuration, the receiver ground electrode may be connected to the environmental ground, either directly or through a pseudo-ground. In a second configuration, the receiver ground electrode may not be in physical contact with any objects, including the human body.

When the transmitter 102 transmits an electro-quasistatic signal through the body channel, a differential alternating current voltage is induced across the receiver signal and ground electrodes. This voltage is of the same electro-quasistatic frequency as the transmitter signal, however, with reduced amplitude. The amount of amplitude reduction depends on the transmitter ground configuration and the receiver ground configuration.

The electrical load 108 on the receiver 104 may utilize the differential alternating current voltage as a power source. For instance, a light-emitting diode connected to the signal electrodes and the ground electrodes may illuminate without requiring a battery. Similarly, a wearable device such as a smartwatch may use alternating current to direct current conversion (AC to DC) to convert the received alternating current voltage into a direct current voltage, followed by a buck-boost converter (not shown in FIG. 1A-B) to regulate the voltage to the appropriate level for operation. The distance between the transmitter 102 and receiver 104 may be as required, for example, ranging from a few centimeters to the longest body distance of the user, such as from head to toe. As long as the transmitter 102 and receiver 104 include signal electrodes in contact with the body, power transfer remains functional.

The human body channel includes three key components. The first component is a body impedance, which represents the impedance of the human body. The second component may be a contact impedance, which represents the impedance at the interface between the signal electrode and the human body. The third component may be a parasitic capacitance, which represents the capacitance between the human body and the environmental ground.

Contact impedance may optimize power transfer. The contact impedance is inversely proportional to the size of the contact area. For example, larger contact areas result in lower impedance. To ensure efficient power transfer, maintaining a contact area of at least one square centimeter may be recommended. Furthermore, for the transmitter 102 and the receiver 104, there may be a parasitic capacitance Cₚₚ between the signal electrode and ground electrode. If the ground electrode of the device is not connected to the environmental ground, there would also be a parasitic capacitance formed between the ground electrode and the environmental ground, such as a return capacitance Cret.

For example, if the transmitter 102 is transmitting an electro-quasistatic alternating current voltage of a certain magnitude, the relationship between transmitted and received voltage varies depending on whether the transmitter 102 and the receiver 104 are ground-connected or ground-floated. When the transmitter 102 is ground-connected, the body voltage may be equal to the transmitted voltage. When the transmitter 102 is ground-floated, the body voltage is determined by a capacitive voltage divider formed by two capacitances such as a return capacitance of the transmitter 102 TX Cret and a capacitance between a body Cbody and a ground. In this configuration, the voltage at the body is a fraction of the transmitted voltage. Further, the body capacitance may be larger than the transmitter capacitance, and in turn the body voltage may be significantly reduced.

Similarly, for the receiver 104, if the receiver 104 is in ground-connected configuration, the received voltage may be equal to the body voltage. If the receiver 104 is ground-floated, the received voltage may further be reduced based on impedance relationships among the parasitic capacitances and load impedance. To maximize received power, the load resistance may need to be impedance-matched based on the receiver configuration. When the receiver 104 is ground-connected, the load resistance may need to be matched to the combined impedance of the body impedance and the contact impedance to ensure efficient signal transfer and minimize signal reflections or losses. This matching helps maintain signal integrity by aligning the electrical characteristics of the receiver 104 with those of the body and contact interfaces. In contrast, when the receiver 104 is ground-floated, the voltage at the receiver Vrx is determined by a voltage divider formed by the combined parallel impedance of parasitic capacitance Cpp and a load resistance Rload, represented as Zx, and an AC impedance of Cret, denoted as Zcret. This indicates that the receiver voltage depends on the proportion of these impedances, where a higher Zx relative to Zcret results in a larger Vrx. This configuration highlights the influence of capacitive and resistive elements on signal attenuation and how the absence of a ground reference allows the capacitive voltage divider effect to determine the received voltage.

Those of ordinary skilled in the art will appreciate that the hardware depicted in FIG. 1A and FIG. 1B may vary for particular implementations. For example, the powering devices 101-1 and 101-2 may include, such as for example, but not limited to, smart-watch, smart wristband, smart eyewear, earbuds, headphones, waistband, and the like. The depicted example is provided for the purpose of explanation only and is not meant to imply architectural limitations with respect to the present disclosure.

In some example embodiments, each of the powering devices 101-1, . . . , 101-N shown in FIG. 1B comprises transceivers for enabling bi-directional power between the powering devices 101-1, . . . , 101-N. Furthermore, a transmitter such as a wearable is coupled to an external network 110. The external network 110 may include, but not limited to, Wireless Personal Area Network (WPLAN), Wireless Local Area Network (W LAN), Wireless Metropolitan Area Network, Wireless Wide Area Network, and the like. The network 110 may be configured to work as the infrastructure that allows the powering devices 101 to connect, exchange information and transfer power with a server 112. The network 110 may establish a connection between powering devices 101, and the server 112, enabling the powering devices 101 to communicate regardless of their physical location. The server 112 may be configured to function as an intermediary, facilitating the seamless flow of data or power signals between the powering devices 101. Further, the server 112 may include a processor (not shown in FIG. 1B) and a memory (not shown in FIG. 1B) coupled to the processor (not shown in FIG. 1B). The memory includes processor-executable instructions, which on execution, cause the processor to perform one or more actions, such as power transfer, data processing, data acquisition, data analysis, power distribution and the like.

Although, FIG. 1B illustrates the powering system 100B communicatively coupled to the server 112 via the network 110, one skilled in the art can envision that the powering system 100B may be connected to networks 110 such as, but not limited to, Wireless Personal Area Network (WPLAN), Wireless Local Area Network (WLAN), Wireless Metropolitan Area Network (MPLAN), Wireless Wide Area Network (WWAN), and the like, and combinations thereof. The network 110 may be configured to work as the infrastructure that allows the powering device 101 to connect and exchange information with the server 112.

In an exemplary embodiment, the transmitter 102 may be configured to transmit electro quasistatic signals to the receiver 104 via a human body channel using an electrostatic coupling. The electro quasistatic signals power the receiver 104. Further, the human body may be electrically connected to the transmitter 102, and the human body channel may be configured to transfer the electro quasistatic signals from the transmitter 102 to the receiver 104. The human body channel may include a body impedance value, a capacitive coupling, a contact impedance, and the like.

In an exemplary embodiment, the receiver 104 may be electrically connected to the human body channel. The receiver 104 may be configured to deliver power to the electrical load 108 of the receiver 104 based on a powering level.

Though few components and subsystems are disclosed in FIGS. 1A and 1B, there may be additional components and subsystems which is not shown, such as, but not limited to, ports, routers, repeaters, firewall devices, network devices, databases, network attached storage devices, user devices, additional processing systems, servers, assets, machineries, instruments, facility equipment, any other devices, and combination thereof. The person skilled in the art should not be limiting the components/subsystems shown in FIGS. 1A and 1B. Although FIGS. 1A and 1B illustrates the devices 101, is connected to the server 112, one skilled in the art may envision that the devices 101, may be connected to several servers 112 located at same/different locations.

Those of ordinary skilled in the art will appreciate that the hardware depicted in FIGS. 1A and 1B may vary for particular implementations. For example, other peripheral devices such as an optical disk drive and the like, local area network (LAN), wide area network (WAN), wireless (e.g., wireless-fidelity (Wi-Fi)) adapter, graphics adapter, disk controller, input/output (I/O) adapter also may be used in addition or place of the hardware depicted. The depicted example is provided for explanation only and is not meant to imply architectural limitations concerning the present disclosure.

Those skilled in the art will recognize that, for simplicity and clarity, the full structure and operation of all data processing systems suitable for use with the present disclosure are not being depicted or described herein. Instead, only so much of the system 100A-B as is unique to the present disclosure or necessary for an understanding of the present disclosure is depicted and described. The remainder of the construction and operation of the system 100A-B may conform to any of the various current implementations and practices that were known in the art.

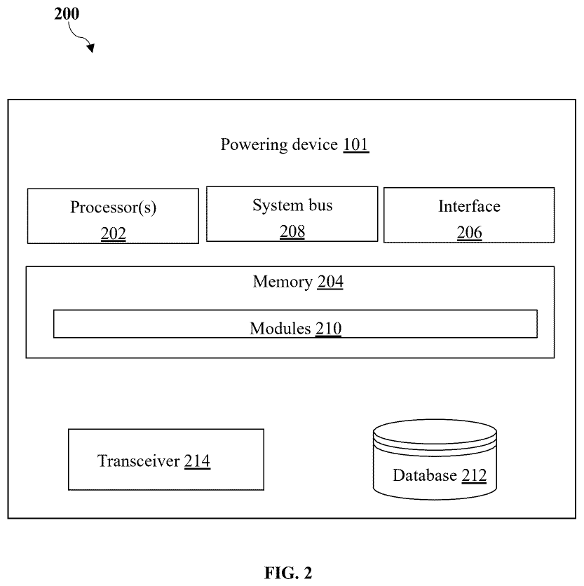

FIG. 2 illustrates a block diagram representation of a powering system 200, such as those shown in FIG. 1, for transferring power to another device using capacitive Electro-Quasi Static Human Body Powering (EQS-HBP), in accordance with an embodiment of the present disclosure. The powering system 200, is similar to the powering devices 101 as shown in FIG. 1. The powering system 200, includes a processor 202, a memory 204 coupled to the processor 202, the memory 204 includes processor-executable instructions in the form of one or more modules 210.

The powering system 200 may further comprise transceiver 214 which acts as both transceiver and receiver to transfer power between other devices in the human body network. Referring to FIG. 2, the powering system 200 may include one or more processor(s) 202 that may be implemented as one or more microprocessors, microcomputers, microcontrollers, digital signal processors, central processing units, logic circuitries, and/or any devices that process data based on operational instructions. Among other capabilities, the one or more processor(s) 202 may be configured to fetch and execute computer-readable instructions stored in a memory 204 of the powering system 200. The memory 204 may be configured to store one or more computer-readable instructions or routines in a non-transitory computer readable storage medium, which may be fetched and executed to create or share data packets over a network service. The memory 204 may comprise any non-transitory storage device including, for example, volatile memory such as random-access memory (RAM), or non-volatile memory such as erasable programmable read only memory (EPROM), flash memory, and the like.

In an embodiment, the powering system 200 may include a communication interface(s) 206. The communication interface(s) 206 may include a variety of interfaces, for example, interfaces for data input and output (I/O) devices, storage devices, and the like. The communication interface(s) 206 may also provide a communication pathway for one or more components of the powering system 200.

In an embodiment, the memory 204 may include a plurality of modules 210 for performing one or more operations within the powering system 200.

The processor 202 is configured to execute program instructions. For example, the processor 202 may be a real processor or a virtual processor. It will be understood that the powering system 200 does not suggest any limitation as to the scope of use or functionality of the described embodiments. The powering system 200 may include, but is not limited to, one or more of a general-purpose computer, a programmed microprocessor, a microcontroller, an integrated circuit, and other devices or arrangements of devices that are capable of implementing the steps that constitute the methods of the present invention.

Exemplary embodiments of the powering system 200 in accordance with the present invention may include one or more servers, desktops, laptops, tablets, smartphones, mobile phones, mobile communication devices, tablets, phablets, and personal digital assistants. In an embodiment, the memory 204 may store software for implementing various embodiments of the present invention. The powering system 200 may include additional components or fewer components. For example, the powering system 200 may include one or more communication interfaces 206, one or more input devices, one or more output devices, and a database 212. An interconnection mechanism (not shown) such as a bus 208, control circuitry, or network, interconnects the components of the powering system 200. In various embodiments, operating system software (not shown) provides an operating environment for various software(s) executing in the powering system 200 using the processor 202 and manages different functions and features of the components of the powering system 200.

The interface 206 allows communication over a communication medium to various other computing entities. The interface 206 provides information such as program instructions, or other data in a communication medium. The communication media may include, but are not limited to, wired or wireless methodologies implemented with electrical, optical, RF, infrared, acoustic, microwave, Bluetooth, IEEE 802.15.6, IEEE 802.15.4, IEEE 802.15.3 compliant networking protocols, or other transmission media.

The input device(s) may include, but are not limited to, a touch screen, a keyboard, mouse, pen, joystick, trackball, a voice device, a scanning device, or any other device that is capable of providing input to the powering system 200. The output device(s) may include, but not be limited to, a user interface on CRT, LCD, LED display, or any other display associated with any of servers, desktops, laptops, tablets, smartphones, mobile phones, mobile communication devices, tablets, phablets and personal digital assistants, printer, speaker, CD/DVD writer, or any other device that provides output from the powering system 200.

Further, the powering system 200 may include a database 212, and the database 212 may include, but not be limited to, magnetic disks, magnetic tapes, CD-ROMs, CD-RWs, DVDs, any types of computer memory, magnetic stripes, smart cards, printed barcodes, or any other transitory or non-transitory medium which can be used to store information and can be accessed by the powering system 200. In various embodiments, the database 212 may contain program instructions and data for implementing any of the described embodiments.

The powering system 200 may execute the transmitter 102 to transmit electro quasistatic signals to the receiver 104 via the human body channel using the electrostatic coupling. The electro quasistatic signals power the receiver 104. Further, the human body may be electrically connected to the transmitter 102. The human body channel is configured to transfer the electro quasistatic signals from the transmitter 102 to the receiver 104, and the human body channel includes the body impedance value, the capacitive coupling, the contact impedance, and the like.

In an exemplary embodiment, the receiver 104 may be electrically connected to the human body channel. The powering system 200 may execute the receiver 104 to deliver power to the electrical load 108 of the receiver 104 based on a powering level. The transmitter 102 and the receiver 104 includes a signal electrode connected to the human body channel. The body impedance value includes an impedance of the human body channel, and the contact impedance includes an impedance at an interface between a signal electrode and the human body channel. Further, the parasitic capacitance Cret includes a capacitance between the human body channel and an environmental ground and a parasitic capacitance Cpp between the signal electrode and the ground electrode. Further, the contact impedance may include a magnitude value being inversely proportional to a contact area size. The body impedance value may be determined using a height of a human body, a cross-sectional area of the human body and a muscle conductivity.

In an exemplary embodiment, the transmitter 102 may include a ground-connected configuration. The ground-connected configuration includes a ground electrode of the transmitter 102 connected in at least two configurations. The at least two configurations may include the ground electrode electrically connected to an environmental ground. Further, the at least two configurations include the ground electrode in close proximity to the environmental ground.

In an exemplary embodiment, the receiver 104 may include a ground-connected configuration, which may include a ground electrode of the receiver 104 connected in at least two configurations. The at least two configurations include the ground electrode electrically connected to the environmental ground. Furthermore, the at least two configurations include the ground electrode in close proximity to the environmental ground.

In an exemplary embodiment, the transmitter 102 may include a ground-floated configuration. The ground-floated configuration may include a floating ground electrode of the transmitter 102 being isolated from the environmental ground. The receiver 104 includes a ground-floated configuration. The ground-floated configuration includes a floating ground electrode of the receiver being isolated from the environmental ground. In an exemplary embodiment, the ground of the transmitter 102 and the ground electrode of the receiver 104 may include a size configurable based on a device form factor. In the ground-connected configuration, the transmitter 102 may be electrically connected to the environmental ground, and a voltage of the human body channel corresponds to a complete electro-quasistatic alternating current voltage of the transmitter 102.

In the ground-floated configuration, the transmitter 102 may be electrically isolated from the environmental ground and a voltage of the human body channel may be determined based on the ratio of Body-to-environmental ground parasitic capacitance (Cbody) and a parasitic capacitance formed between the transmitter ground electrode and the environmental ground (Cret).

In an exemplary embodiment, to deliver the power to the electrical load of the receiver 104 based on the powering level, the receiver 104 may determine if the receiver 104 is in ground-floated configuration and if a parasitic capacitance between the received signal and the ground electrode of the receiver (Cpp) is larger than a parasitic capacitance formed between the ground electrode of the receiver 104 and the environmental ground (Cret). Further, the powering system 200 may execute the receiver 104 to configure a load resistance value of the electrical load to be impedance-matched to the parasitic capacitance between the received signal and the ground electrode of the receiver (Cpp). Furthermore, the powering system 200 may execute the receiver 104 to deliver power to the electrical load of the receiver based on the configured load resistance value.

In an exemplary embodiment, to power a power unit (not shown) of the receiver 104 upon receiving the electro quasistatic signals, the receiver 104 may determine if the receiver 104 is in ground-floated configuration and if the parasitic capacitance between the received signal and the ground electrode of the receiver Cpp value is lesser than the parasitic capacitance formed between the ground electrode of the receiver and the environmental ground (Cret). Further, the receiver 104 may configure a load resistance value of the electrical load to be impedance-matched to the parasitic capacitance formed between the ground electrode of the receiver and the environmental ground (Cret). Furthermore, the receiver 104 may deliver power to the electrical load of the receiver 104 based on the configured load resistance value.

In an exemplary embodiment, to deliver power to the power unit of the receiver upon receiving the electro quasistatic signals, the receiver 104 may determine if the receiver 104 is in ground-connected configuration. Furter, the receiver 104 may match a load resistance value of the electrical load with an impedance of the body impedance value and the contact impedance. Furthermore, the receiver 104 may deliver power to the electrical load 108 of the receiver 104 based on the matched load resistance value.

In an exemplary embodiment, the transmitter 102 may adjust a frequency of the EQS signals transmitted. Further, the receiver 104 may deliver power using a differential alternating current voltage across a signal electrode and a ground electrode in response to the received electro-quasistatic signals. The differential alternating current voltage includes a frequency corresponding to a frequency of the received electro-quasistatic signals and an amplitude dependent on a grounding configuration of the transmitter 102 and the receiver 104. Further, the receiver 104 may include the electrical load 108 electrically connected to a signal electrode and the receiver ground electrode. Further, the electrical load 108 may extract power from the differential alternating current voltage. The transmitter 102 may transmit the electro-quasistatic signals until the signal electrode of the transmitter 102 remain in conductive contact with the human body channel.

In an exemplary embodiment, the powering system 200 may include one or more wearable devices (not shown in FIG. 2) comprising a first transceiver and a central system (not shown) comprising a second transceiver. The first transceiver and the second transceiver alternately operate as a transmitter and as a receiver to transfer bi-directional power between the first transceiver and the second transceiver.

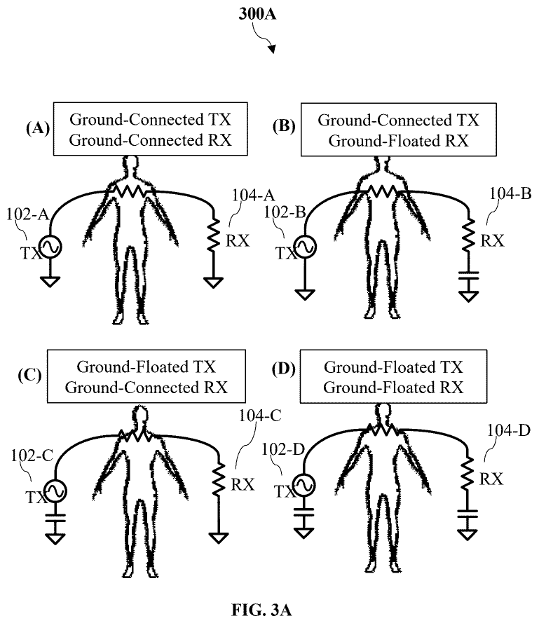

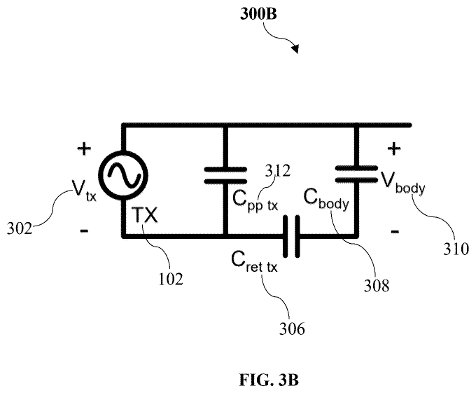

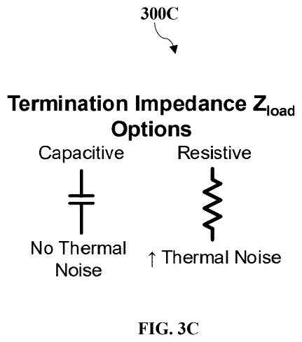

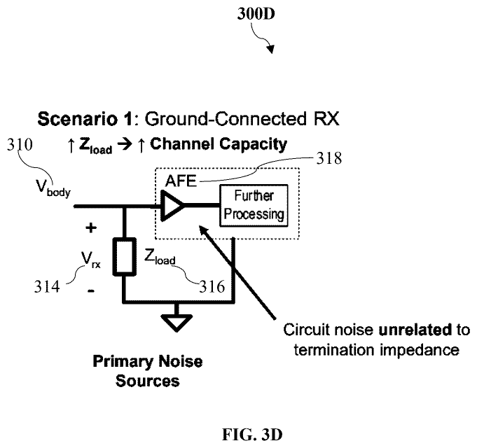

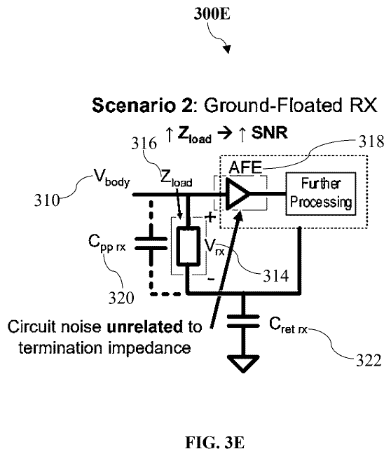

FIG. 3A illustrates schematic representations of a plurality of example ground electrode configurations 300A of transmitter 102 and receiver 104, in accordance with an embodiment of the present disclosure. The part (A) in FIG. 3A depicts a ground configuration of the ground electrode at the transmitter 102-A and the receiver 104-B. Specifically, FIG. 3A depicts a ground-connected transmitter (Tx) 102 and a ground-connected receiver (Rx) 104. In this configuration, both the transmitter 102 and receiver 104 are connected to the environmental ground.

The body acts as a conductive medium 106, transferring EQS signals from the transmitter 102 to the receiver 104. As, the transmitter 102 is ground-connected, the voltage of the body such as the conductive medium 106 closely matches the transmitted voltage. The receiver 104 being ground-connected allows for efficient power transfer, as the differential voltage between the signal and ground electrodes at the receiver 104 is maximized. This configuration may provide stable and efficient power delivery due to the common ground reference between the Transmitter (TX) 102 and the Receiver (RX) 104.

The part (B) in FIG. 3A depicts a ground-connected transmitter (Tx) 102-B and ground-floated receiver (Rx) 104-B. The transmitter 102 is ground-connected, where the body voltage is approximately equal to the transmitted voltage. Further, the receiver 104 is ground-floated, where its ground electrode is not directly connected to the environmental ground. In this case, the receiver 104 relies on parasitic capacitance (Cpp) between its ground electrode and the environment to complete the circuit. Since the receiver ground is floating, the induced voltage at the receiver 104 may be reduced, potentially affecting power transfer efficiency. This configuration is useful for applications where a ground connection is not feasible at the receiver end.

The part (C) in FIG. 3A depicts a ground-floated transmitter (Tx) 102-C and ground-connected receiver (Rx) 104-C. The transmitter 102 is ground-floated, where its ground electrode is isolated from the environmental ground. The receiver 104 is ground-connected, providing a stable reference for power extraction. In this case, the body voltage is determined by the capacitance ratio between the transmitter's parasitic capacitance (Cᵣₑₜ) and the body capacitance (C_{body}), leading to a reduction in the effective body voltage. As the transmitter 102 is floating, the body voltage is significantly lower than in the ground-connected case.

The part (D) in FIG. 3A depicts a ground-floated transmitter (tx) 102-D and ground-floated receiver (rx) 104-D. Both the transmitter 102 and receiver 104 are ground-floated, where neither has a direct connection to the environmental ground. The power transfer in this configuration relies entirely on capacitive coupling, including the parasitic capacitances between the transmitter 102, receiver 104, and the environment. Since both ground electrodes are floating, the differential voltage at the receiver 104 may be further reduced due to limited capacitive coupling. This setup is the most challenging for efficient power transfer, as it depends on the balance between Cₚₚ (parasitic capacitance between received signal and receiver ground) and Cᵣₑₜ (return capacitance between receiver ground and environmental ground). Power optimization in this case may require impedance matching techniques to maximize energy transfer.

FIG. 3B illustrates a circuit diagram of a capacitive Electro-Quasi Static Human Body Powering (EQS-HBP) using a Human Body Communication (HBC) network 300B, in accordance with an embodiment of the present disclosure. FIG. 3C illustrates a circuit diagram for termination impedance options 300C, in accordance with an embodiment of the present disclosure. FIG. 3D illustrates a circuit diagram for ground-connected receiver 300D with high impedance termination boosts channel capacity, in accordance with an embodiment of the present disclosure. FIG. 3E illustrates a circuit diagram for ground-floated receiver 300E with high impedance termination boosting Signal-to-Noise Ratio (SNR), in accordance with an embodiment of the present disclosure.

In an example, the need for a channel and circuit analysis of capacitive EQS-HBP stems from the voltage mode communication technique in capacitive EQS-HBC. Traditional wireless communication systems use power mode communication, where maximizing the received signal power leads to maximizing the overall system performance, and the signal propagation through the air channel is primarily described by power transmission. In contrast, the capacitive EQS-HBC operates at a wavelength larger than the scale of the body. While a time-varying E-field is present, the H-field is not significant, in turn

$$\frac{dH}{dt}$$

does not substantially impact the E-field. As a result, the system may be primarily approximated as electro-quasistatic. Therefore, capacitive EQS-HBC is referred to as voltage mode communication and optimizing the system performance requires high impedance termination leaving the channel characteristics of lower to medium impedance termination range unexplored. While high-impedance termination is commonly employed in capacitive EQS-HBC, providing a clear, intuitive explanation may facilitate better understanding, enabling easier comparisons with capacitive EQS-HBP.

The need for high-impedance termination over impedance matching in capacitive EQS-HBC is to maximize channel capacity. This concept may be illustrated through two distinct scenarios involving signal-to-noise ratio (SNR) and channel bandwidth.

In the first scenario, the RX is a ground-connected device (without Cᵣₑₜ), as depicted in FIG. 3D. Here, the primary noise sources include input termination resistance and circuit noise, which can be expressed as shown in equation 1 below:

$${V}_{N}^{2} = 4 kTR + {V}_{{N}_{c k t}}^{2} \qquad Equation 1$$

The received voltage can be approximated as shown in equation 2 below:

$${V}_{r x} = \frac{R}{R + {Z}_{body}} * {V}_{tx} \qquad Equation 2$$

When R>>Z_{body}, Vᵣₓ 302≈V_{body} 310, in which FIG. 3C, and further increment of R may not improve Vᵣₓ. Instead, it increases the 4 kTR noise, degrading the SNR. This issue can be mitigated by employing capacitive termination, as only the equivalent series resistance (ESR) of the capacitor will contribute to the noise. Despite the SNR may eventually plateau when Z_{load}>>Z_{body}, increasing the Z_{load} 316 may enhance the body channel bandwidth. According to Shannon's capacity theorem (Capacity=BW log₂(1+SNR)), higher bandwidth leads to increased channel capacity, enabling either higher data rates or reduced energy consumption for a given data rate. Therefore, maximizing the Z_{load} 316 is desirable. The Zload 316 may be connected to Analog Front End (AFE) 318.

In the second scenario, the RX 104 is a ground-floated device (with Cᵣₑₜ 322) and C_{pp rx} 320, as shown in FIG. 3E. The received voltage can be approximated by

$${V}_{r x} = \frac{{Z}_{l o a d}}{{Z}_{l o a d} + {Z}_{{C}_{r e t}}} * {V}_{body}$$

and V_{body} 310 is constant regardless of Z_{load} 316 due to Z_{C}_{ᵣₑₜ}>>Z_{body}, resulting in an SNR expression of

$$SNR = \frac{{V}_{r x}^{2}}{{V}_{N}^{2}} ∝ {Z}_{l o a d}$$

when Z_{load}<<Z_{C}_{ᵣₑₜ}. Given that Cᵣₑₜ typically falls within the pico-farad range, it presents a high AC impedance, exceeding 100 kΩ at 1 MHz, making the Z_{load}<<Z_{C}_{ᵣₑₜ} condition generally applicable. This condition favors increasing Z_{load} as much as possible. In the extreme case where, equation 3 is:

$${Z}_{l o a d} \to ∞ , {V}_{r x} = {V}_{body} * \frac{{C}_{ret}}{{C}_{ret} + {C}_{pp}} \qquad Equation 3$$

Additionally, with interference, increasing Z_{load} may not necessarily improve the signal-to-interference ratio (SIR). If the interference frequency is close to the signal frequency, altering Z_{load} will have no effect on SIR. However, if the interference frequency is significantly higher (e.g., 2.4 GHz), the low pass filtering properties of the body channel will naturally attenuate it. Conversely, if the interference frequency is significantly lower (e.g., 50-60 Hz power line interference), a high-pass filter could be employed to attenuate the interference without changing Z_{load}. While capacitive EQS-HBC focuses on maximizing channel capacity through high-impedance termination, capacitive EQS-HBP aims to maximize Pᵣₓ, which necessitates impedance matching. The following sections examine the biophysical model in detail to identify the key elements for achieving impedance matching.

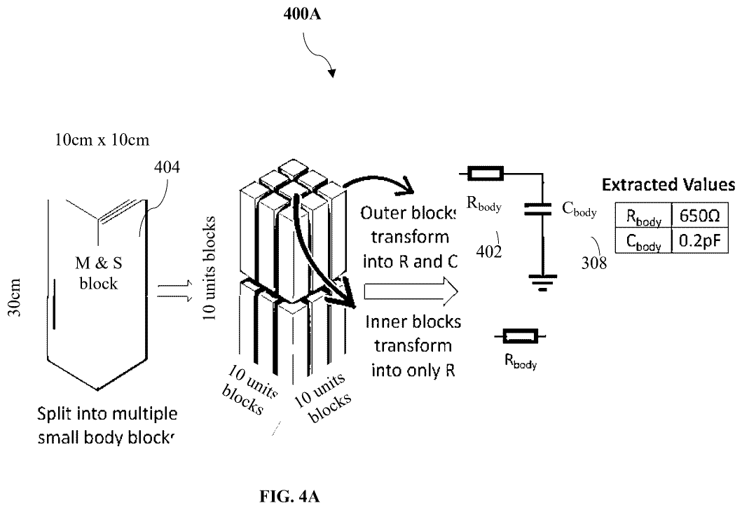

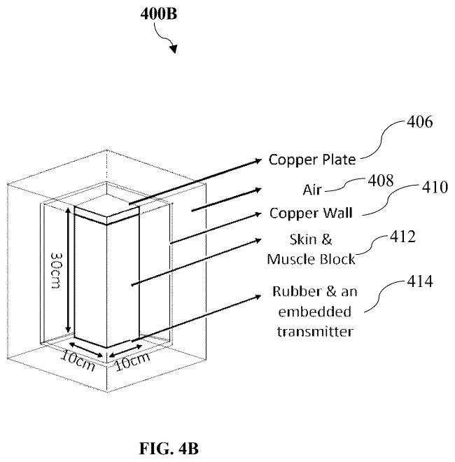

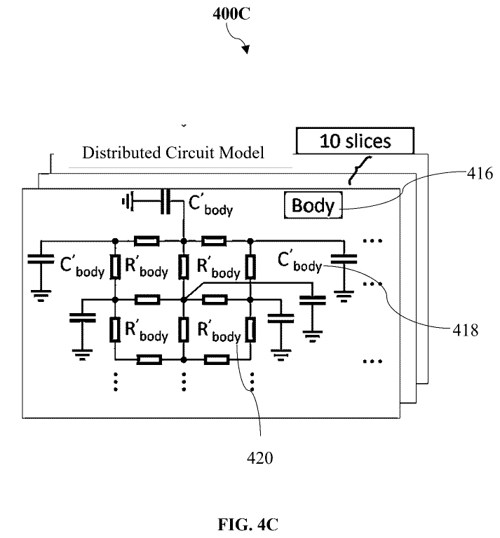

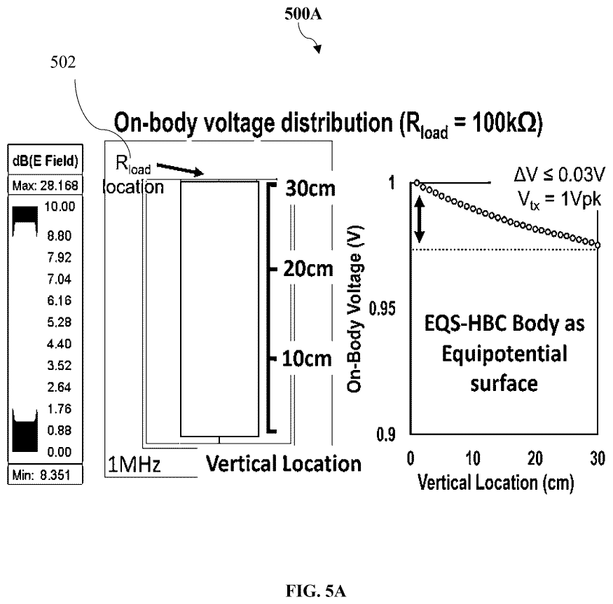

FIG. 4A illustrates schematic representations of generating a distributed resistor-capacitor (RC) circuit 400A from a pre-defined dimensions of a skin block and a muscle block 404, by dividing it into smaller unit blocks and combining the unit blocks into a circuit, in accordance with an embodiment of the present disclosure. FIG. 4B illustrates a schematic representation of a Finite Element Modeling (FEM) 400B of a body model for a skin block and a muscle block, in accordance with an embodiment of the present disclosure. FIG. 4C illustrates a circuit diagram representation of a distributed circuit model 400C after combing smaller unit blocks, in accordance with an embodiment of the present disclosure.

Conventional systems are experimented between 10 KHz and 1 MHz, modeling the body channel for capacitive EQS-HBC and generating values for the different elements of the circuit model. The body is modeled as a network of resistors and capacitors. The exact values of resistor and capacitor can vary between subjects and environments; however, a typical range of values is proposed. However, as the experiments are performed with high-impedance termination, the insights may not apply readily too low to medium impedance termination scenarios. The conventional systems may have calculated the peak power transfer for ground-floated TX and RX scenario. However, the circuit model in conventional systems considers body as an equipotential surface with channel loss dominated by parasitic capacitance, leaving impedance matching for maximum Pᵣₓ unexplored. Furthermore, the conventional systems may focus on the TX circuit optimization, leaving the RX circuit optimization unexplored.

Another conventional system may model the body channel for capacitive EQSHBP as a capacitive dominant circuit with the body channel as C_{B} and R_{B}, and explored the ground-floated TX and RX scenario. The body channel has not been studied across termination impedance, with optimization focusing solely on TX. Yet another conventional system efforts to improve capacitive EQS-HBP have largely relied on models proposed for EQS-HBC. Optimization efforts have been mainly confined to TX instead of exploring the effect of R_{body}, the device parameters, such as contact area size and Cᵣₑₜ, and the RX circuit theory to increase Pᵣₓ. Although, conventional systems focus on the EQS region, it is possible to transfer power through the body channel above the EQS region, which may be a body-coupled powering (BCP). When the wavelength approaches and is smaller than the body dimension, the body starts to become radiative. HBP biophysical modeling for that region may need to include the radiative loss as part of the modeling, which can be omitted in the EQS region. Furthermore, as the body becomes radiative, the on-body voltage distribution starts to deviate from that of the EQS region and may share more similarities with a quarter-wavelength antenna.

Within the EQS region, conventional systems have modeled body channel using distributed analysis and lumped analysis. In distributed analysis, the body is broken into many smaller units, and each unit is characterized and represented through passive components such as resistors and capacitors. In comparison, in lumped analysis, the body is treated as a homogeneous subject and represented by only a few resistors and capacitors. Although lumped analysis lacks the level of detail and accuracy of distributed analysis, it does capture the essential phenomenon of the body channel in the region of interest and facilitates intuitive interpretation of results. Furthermore, lumped analysis aids in the practical design of body-based communication and powering systems by highlighting the most important components, similar to the first few basis vectors in the principal component analysis. For example, the conventional systems have shown the biophysical model for capacitive EQS-HBC can be reduced to only R_{body} and C_{body}, and it is even possible to omit R_{body} if high impedance termination is used.

The proposed system investigates the physical phenomenon of the biological body channel for capacitive EQS-HBP through distributed analysis to develop an intuitive lumped model that captures the biophysical behaviors.

Maximizing Pᵣₓ requires impedance matching, necessitating an investigation into modeling the body in the lower impedance range. Modeling the body channel in simulation is crucial to discern the second-order effects from the first-order effects that often outbreak physical experiments, facilitating a clearer understanding of the primary influences on Pᵣₓ. Hence, the simplified body is analyzed through finite element modelling (FEM) based simulation using, for example, Ansys High-Frequency Structure Simulator (HFSS) shown in FIG. 4B and distributed resistor-capacitor (RC) circuit 400C, as shown in FIG. 4C. The FEM body model may include a copper plate 406, an air 408, a copper wall 410, a skin and muscle block 412, and a rubber and an embedded transistor 414.

In a capacitive EQS-HBP, the TX 102 couples an AC signal onto the body, and the RX 104 is placed on the body to drive a load using the coupled AC signal. The TX and RX may have their ground floating or connected to the environmental ground. The main difference between ground-floated and ground-connected is the presence and absence of Cᵣₑₜ. The Cᵣₑₜ introduces a high series-connected AC impedance and thus reduces the amount of current into and out of the system. This behavior could be captured by analyzing the body from low to high R_{load}. Thus, in the HESS simulation, both the TX and RX are ground-connected, with R_{load} sweeping across the resistance range. Furthermore, to simplify the analysis and capture major first-order effects, the simplified body model comprises only muscle and skin.

In the distributed RC circuit 400C, the body 416 is broken into interconnected unit blocks, as shown in FIG. 4C. The effect of skin impedance is negligible when analyzing R_{body} 402 as Zₛₖᵢₙ<<R_{body} (Cₛₖᵢₙ>500 pF for 4 cm²)). Thus, each unit block comprises a unit resistor, representing muscle unit impedance, and a unit capacitor, representing unit C_{body} 308. Depending on if other unit blocks fully enclose the unit block, the unit C_{body} 308 may be absent. The RC circuit 400C may include C′_{body} 418, and a R′_{body} 420.

As established in earlier sections, E-field predominate in the EQS range. Thus, R_{body} may need to be dependent on the body dimension and the bulk material (muscle) conductivity and can be approximated using equation 4 below:

$${R}_{body} \approx F ( v , σ ( f ) ) = {H}_{b} * \frac{1}{{A}_{b}} * \frac{1}{σ ( f )} \qquad Equation 4$$

where H_{b} is the height, A_{b} is the toro cross-sectional area, and f is the operating frequency: HFSS and distributed circuit simulations are conducted across two ends of the impedance and EQS frequency range to verify this equation. Furthermore, using the same R_{body} and C_{body}, calculations using the lumped circuit model are also compared.

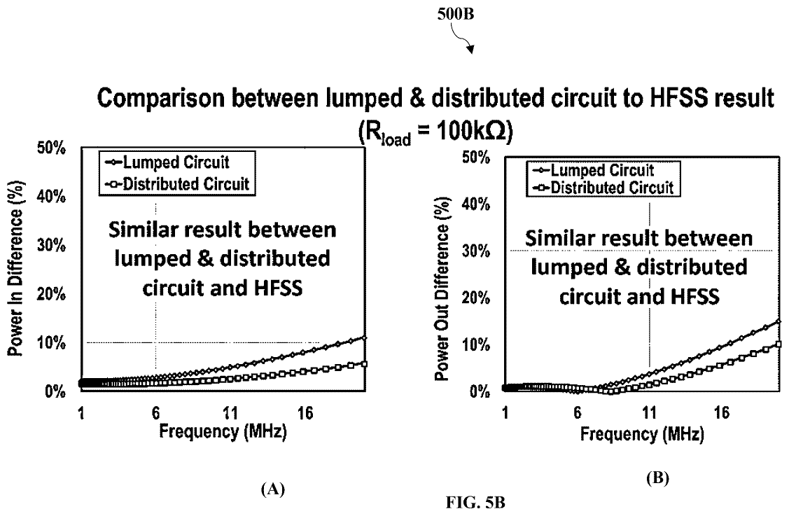

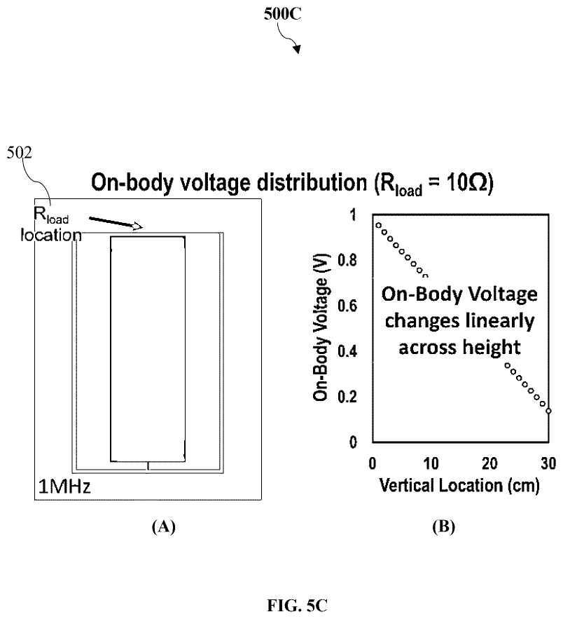

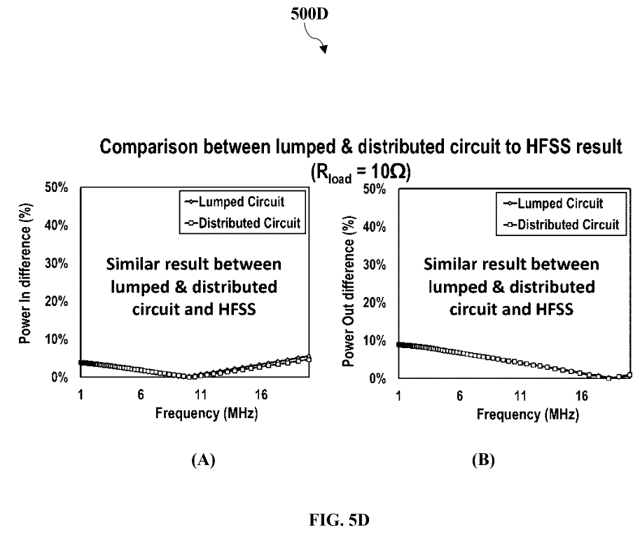

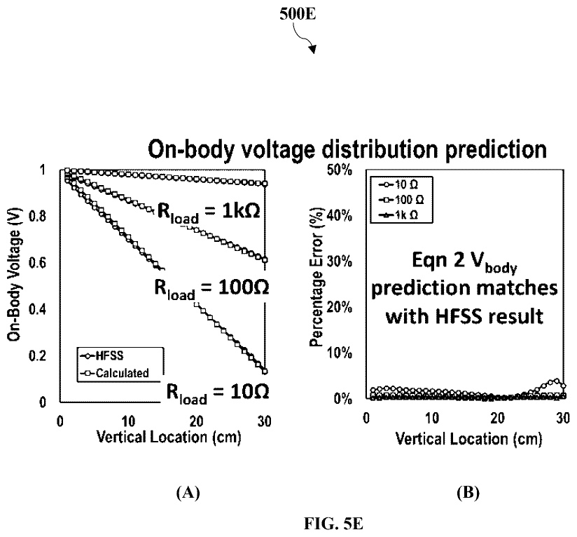

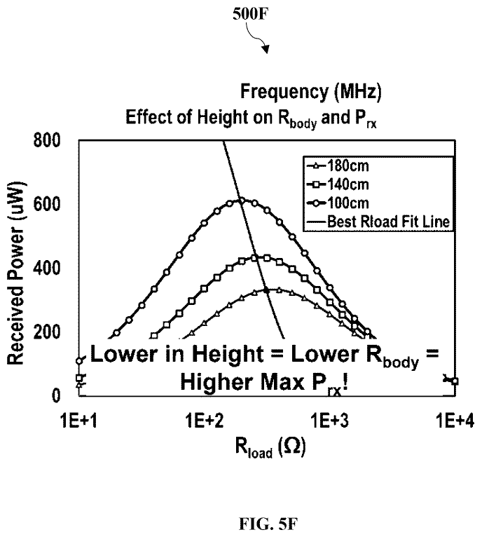

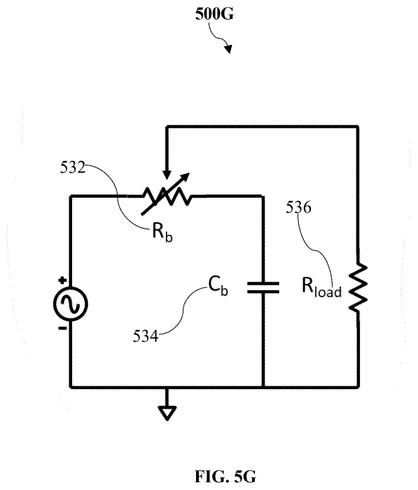

For example, experiment results in FIGS. 5A-5D depict that all three methods 500A, part A and B of 500B in FIG. 5B, part A and B of 500C in 500C, and part A and B of 500D in 500D yield similar trends and values for input and output power. The values align with each other better at lower frequency as compared to higher frequency but overall, the differences≤10%. Furthermore, R_{load} location 502 includes at higher R_{load}, the voltage variation across the body is minimal, showing the body channel as equipotential. At lower R_{load}, in the on-body voltage changes linearly across the body, suggesting a uniform distribution of R_{body} across height, enabling location-based on-body voltage prediction using equation 5 below:

$$V ( loc ) = {V}_{tx} - {R}_{b} ( loc ) \times I ( {R}_{l o a d} , {R}_{b} ) \qquad Equation 5$$

As shown in part A and B of graph 500E in FIG. 5E, the calculated result using the equation 5 aligns closely with the simulation result across multiple R_{load}. The percentage error in all cases is less than 5%, verifying that R_{body} is uniformly distributed across height.

In the EQS range, the body may be modeled as a uniformly distributed resistor (R_{body}), 532 and C_{b} 534, as shown in FIG. 5G, with R_{body} 532 calculated using the equation 4. When R_{load}>>R_{body}, the on-body voltage shows minimal variation, allowing the body channel to be approximated as equipotential, consistent with the general model of capacitive EQS-HBC. The When R_{load} 536 is comparable to R_{body}, the on-body voltage varies linearly FIG. 5E, and can be predicted using equation 5. FIG. 5F demonstrates the effect of R_{body} on Pᵣₓ; a shorter person with similar body diameter has a lower R_{body}, resulting in higher peak Pᵣₓ. This section also validates that the lumped circuit model still describes circuit behavior within the EQS region.

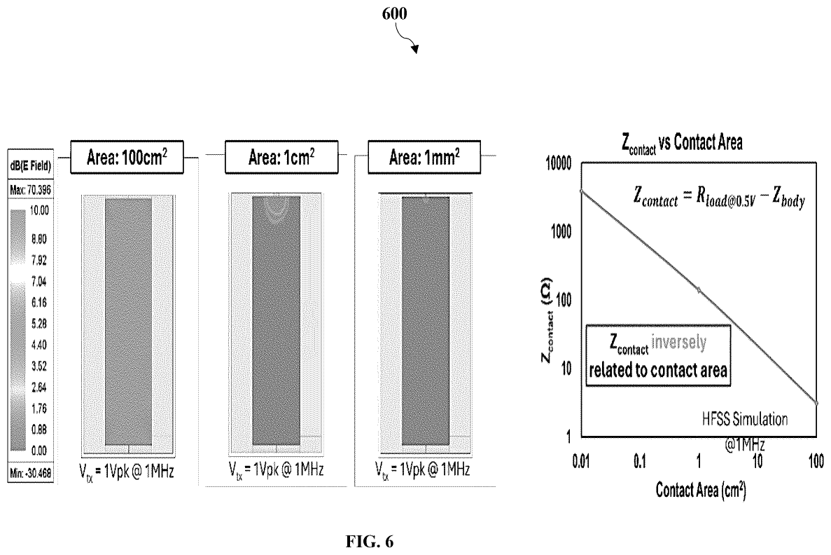

FIG. 6 illustrates heatmap diagram representations of impact of contact area 600 along with comparison of contact impedance and contact area, in accordance with an embodiment of the present disclosure.

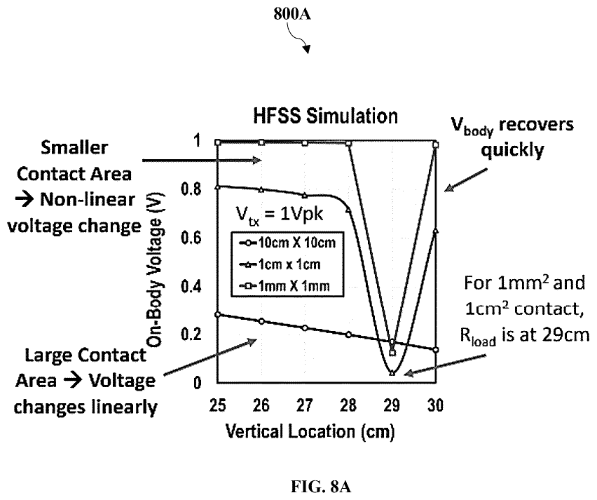

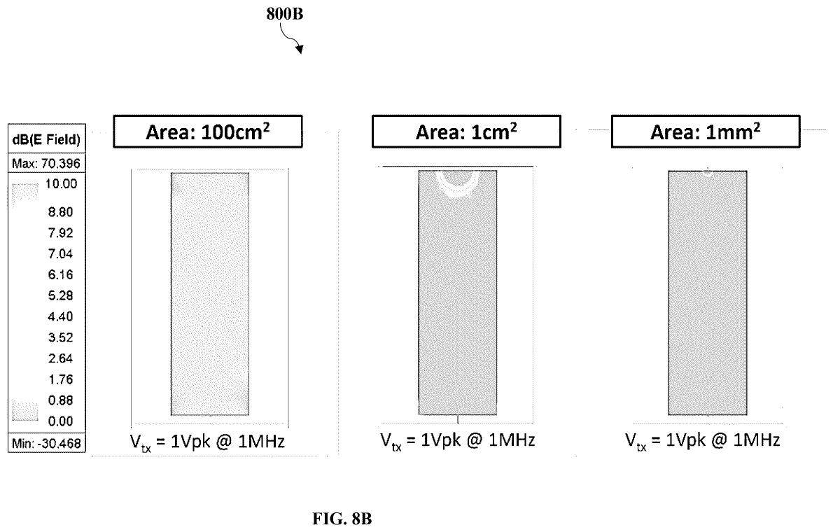

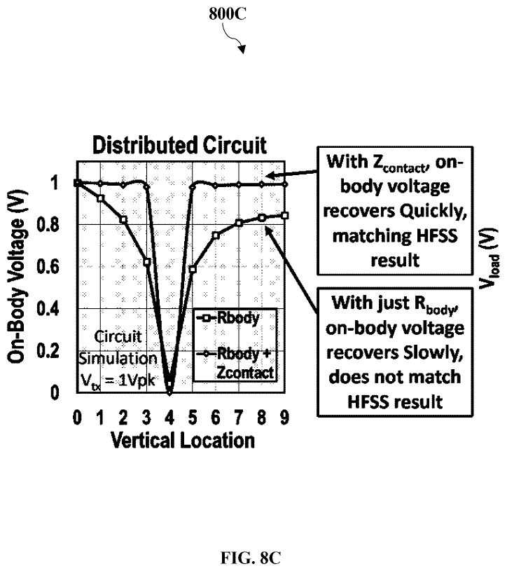

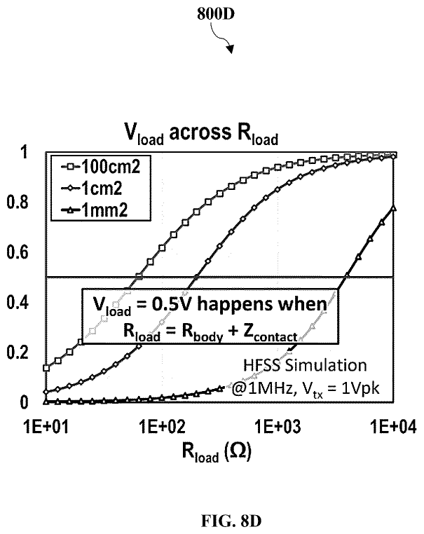

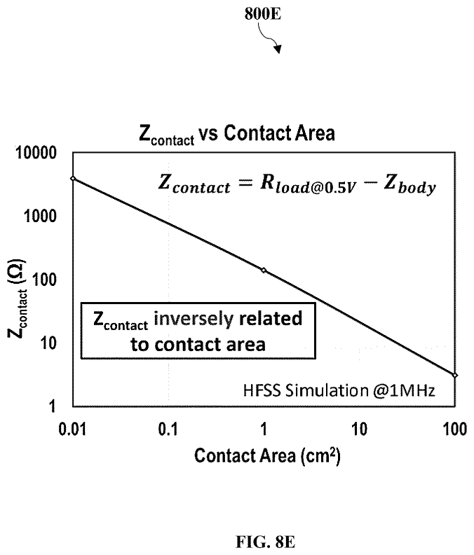

During simulation, another critical observation that impacts Pᵣₓ is related to the contact area. The simulation results in graph diagram 800A, shown in FIG. 8A, shows that at a larger contact area, the on-body voltage change is linear, and the body behaves as a uniformly distributed resistor. However, at a lower contact area, the on-body voltage variation across height changes non-linearly, and when the contact area is very small, the body approaches equipotential 802, 804 except at the point of load. Modeling this behavior is crucial as the typical wearable contact area is in the order of 1 cm², and the typical brain implantable contact area is in the order of 1 mm².

To investigate this behavior, HFSS simulations 600 and 800B are conducted in FIG. 8B and FIG. 6. The bottom of the body block connects to the ground-connected TX that outputs a 1 MHz 1 Vpk signal. The top of the body block connects to a ground-connected R_{load}. The R_{load} connects to the body through a perfect conductor of varying contact area: 10 cm×10 cm, 1 cm×1 cm, and 1 mm×1 mm. The voltage across the R_{load} is measured as V_{load} with a resistance sweep across contact areas, and graph 800D shown in FIG. 8D.

For the lumped circuit model shown in FIG. 5G, if the pole frequency of the RC circuit (R_{body} and C_{body}) is much higher than the operating frequency, minimal current flows through C_{body}. This allows the circuit to be simplified to a resistance-dominated model, with node voltages calculated using the resistor ladder formula. Consequently, V_{load} can be approximated as

$$\frac{{V}_{t x}}{2}$$

when R_{load}=R_{body}. As shown in graph 800E in FIG. 8E, achieving

$$\frac{{V}_{t x}}{2}$$

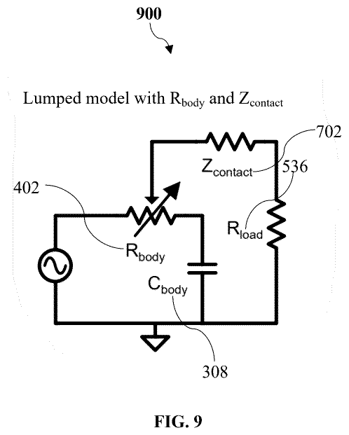

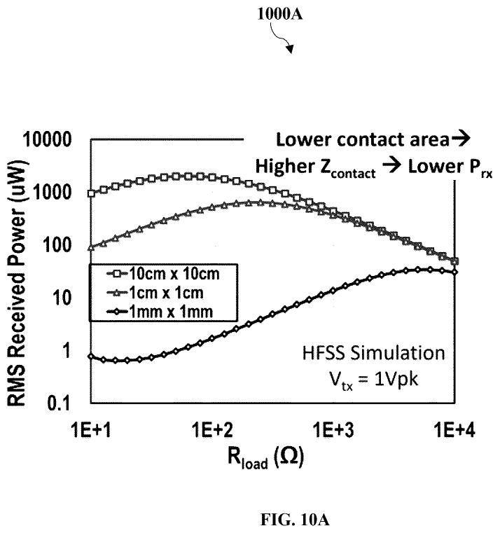

requires that the R_{load} increase by one magnitude order when the contact area decreases by one magnitude order. Since body dimensions and operating frequency are constant across these simulations, R_{body} remains constant. Therefore, an additional impedance, named contact impedance (Z_{contact}) 814, exists at the load point, with its value dependent on the contact area size. The updated circuit diagram, incorporating Z_{contact}, is shown in FIG. 9.

The effect of Z_{contact} is further demonstrated in graph 800C in FIG. 8C. The same simulation is conducted in both HESS and distributed circuit models, with and without Z_{contact}. With only R_{body}, the distributed circuit simulation does not align with the HFSS simulation results in terms of on-body voltage variation trends. However, with Z_{contact} added, the distributed circuit simulation results align closely with those of HFSS. By incorporating Z_{contact}, the distributed circuit model effectively represents the voltage changes observed in HFSS.

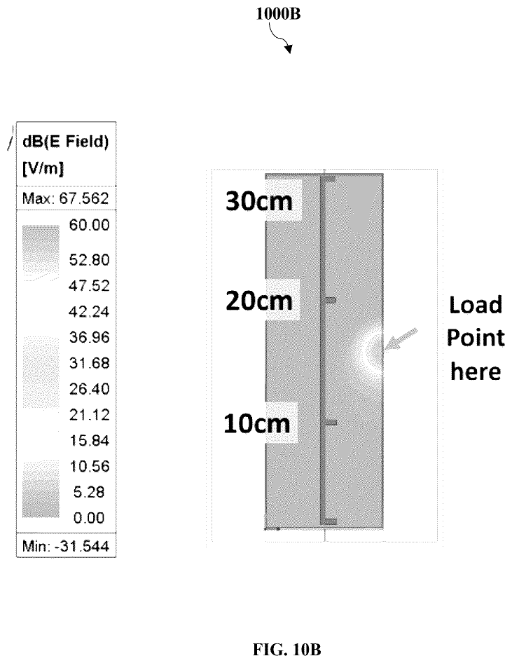

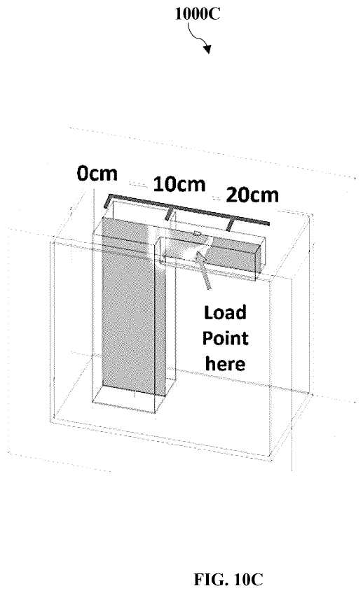

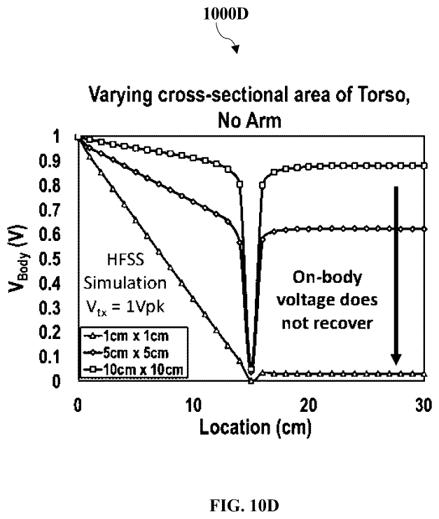

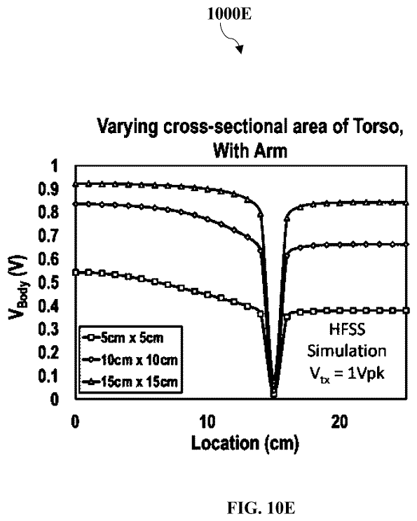

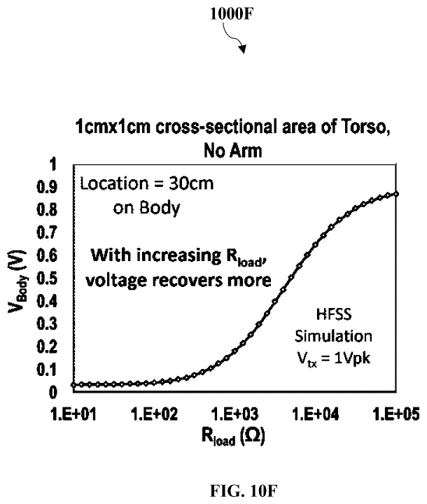

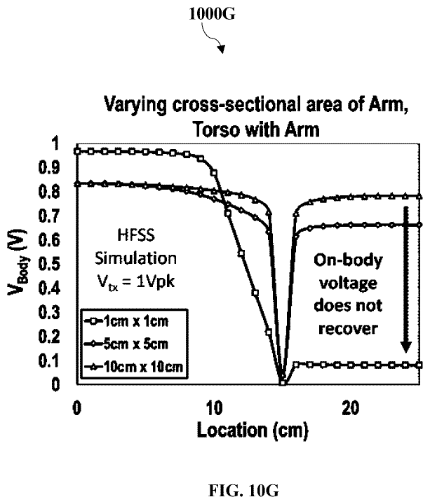

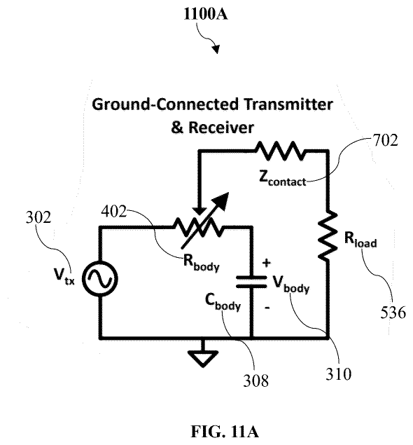

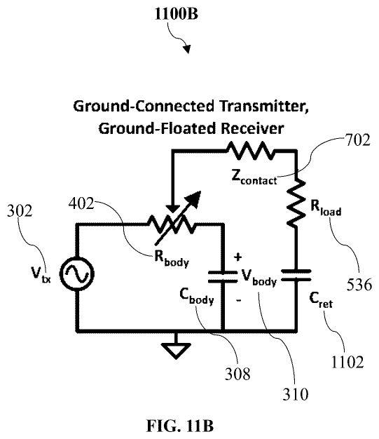

The presence of an area-dependent impedance at the contact point is the second essential component in the lumped circuit model 900, completing the first-order biophysical model of the body for capacitive EQS-HBP. Z_{contact}, shown in FIG. 8E, exhibits an inverse relationship with contact area. At around 1 cm² or smaller, Z_{contact}≥R_{body}. The impact of Z_{contact} is illustrated in graph 1000A in FIG. 10A, where a larger contact area leads to a higher peak Pᵣₓ. Intuitively, when R_{load}<<R_{body}, the small size of the contact area restricts the free flow of electrons through the load to the ground, causing a build-up of electrons around the contact point, leading to a rapid drop in on-body voltage (thus Z_{contact}) near the contact location (FIG. 6). The origin of Z_{contact} requires further investigation and may be influenced by multiple factors. One hypothesis is that Z_{contact} is linked to R_{body} through dimensions, with lower contact areas yielding higher effective R_{body} at the contact point compared to larger areas, as indicated by the inverse relationship in equation 4. Another hypothesis is that Z_{contact} is related to skin impedance, which is typically neglected in R_{body} calculations. Further research into these hypotheses is necessary to fully understand the origin of Z_{contact} and its frequency dependence. For practical applications, on-body devices with larger contact areas will yield higher available power, and typical wearables should aim for a contact area of at least 1 cm².

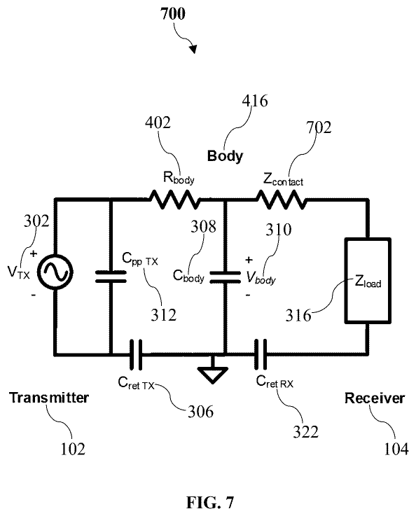

FIG. 7 illustrates a circuit diagram for a transmitter and a receiver in a capacitive Electro-Quasi Static Human Body Powering (EQS-HBP) circuit 700, according to an example embodiment of the present disclosure. The EQS-HBP circuit 700 includes a transmitter 102 side and a receiver 104 side, and a body 416. Further, the EQS-HBP circuit 700 includes a VTx 302, a Cret Tx 306, a Cbody 308, a Vbody 310, a Cpp Tx 312, a Zload 316, a Cret Rx 322, a Rbody 402, and a Zcontact 702.

The electro-quasistatic human body powering system uses the human body 416 as a medium for power transfer, minimizing electromagnetic radiation while enhancing signal containment and efficiency. The system 700 comprises three main components: a transmitter 102, a receiver 104, and the human body channel such as the conductive medium 106.

The transmitter 102 generates, couples, and adjusts the electro-quasistatic signal, which can be a periodic signal in the form of either a square wave or a sine wave. The transmitter 102 employs various methods, such as direct current to alternating current conversion, to generate this electro-quasistatic signal. The transmitter 102 may include two accessible external nodes such as the ground electrode and the signal electrode. To enable power transfer, the transmitter signal electrode must be in contact with or in very close proximity, less than half a centimeter, to the human body. The electrode can exist in various forms and sizes, ranging from a bare jumper wire to a large metallic surface.

The ground electrode of the transmitter has two distinct configurations. In the first configuration, the transmitter ground electrode is electrically connected to the environmental ground. This connection can be direct, such as a wire connected to a wall-mounted electrical outlet ground, or indirect, such as a metallic plate placed on a large object like a table, acting as a pseudo-ground. In the second configuration, the transmitter ground electrode is not connected to the environmental ground. In this case, the transmitter typically has a mobile power source, such as a battery, and is lifted in the air with its ground electrode not in contact with any objects, including the human body.

The receiver is designed to receive power from the transmitter through the body channel capacitively. Like the transmitter, the receiver consists of a signal electrode and a ground electrode. To enable power reception, the receiver signal electrode must be in contact with or in very close proximity, less than half a centimeter, to the human body. The receiver ground electrode has two configurations. In the first configuration, the receiver ground electrode is connected to the environmental ground, either directly or through a pseudo-ground. In the second configuration, the receiver ground electrode is not in physical contact with any objects, including the human body.

When the transmitter transmits an electro-quasistatic signal through the body channel, a differential alternating current voltage is induced across the receiver signal and ground electrodes. This voltage is of the same electro-quasistatic frequency as the transmitter signal but reduced in amplitude. The amount of amplitude reduction depends on the transmitter and receiver ground configurations. The electrical load on the receiver utilizes this differential alternating current voltage as a power source. For instance, a light-emitting diode connected to the signal and ground electrodes can illuminate without requiring a battery. Similarly, a wearable device such as a smartwatch can use alternating current to direct current conversion to convert the received alternating current voltage into a direct current voltage, followed by a buck-boost converter to regulate it to the appropriate level for operation. The distance between the transmitter and receiver is flexible, ranging from a few centimeters to the longest body distance of the user, such as from head to toe. As long as the transmitter and receiver have their signal electrodes in contact with the body, power transfer remains functional.

The human body channel consists of three key components. The first component is body impedance, which represents the impedance of the human body. The second component is contact impedance, which represents the impedance at the interface between the signal electrode and the human body. The third component is parasitic capacitance, which represents the capacitance between the human body and the environmental ground.

Contact impedance plays a critical role in optimizing power transfer. It is inversely proportional to the size of the contact area, meaning that larger contact areas result in lower impedance. To ensure efficient power transfer, maintaining a contact area of at least one square centimeter is recommended. The invention also incorporates a biophysical model of the human body to accurately represent its impedance. The body impedance is mathematically modeled using the equation 6 below:

$${R}_{b} \approx {H}_{b} * \frac{1}{{A}_{b}} * \frac{1}{σ ( f )} \qquad Equation 6$$

where H_{b} represents the body's height, A_{b} is the cross-sectional area, and σ(f) is the frequency-dependent conductivity of muscle. Furthermore, for the transmitter 102 and the receiver 104, there exists a parasitic capacitance between the signal and ground electrode, named Cpp 312. If the ground electrode of the device is not connected to the environmental ground, there would also be a parasitic capacitance formed between the ground electrode and the environmental ground, named Cret 306, 322. In combination, a complete biophysical model of the human body, transmitter, and receiver with contact impedance is developed. This model facilitates efficient design and analysis of the system.

If the transmitter 102 is transmitting an electro-quasistatic alternating current voltage of a certain magnitude, the relationship between transmitted voltage V_{Tx} 302 and received voltage varies depending on whether the transmitter and receiver are ground-connected or ground-floated. When the transmitter is ground-connected, the body voltage equals the transmitted voltage. When the transmitter is ground-floated, V_{body} 310 is V_{Tx} 302 and Cret with Cbody, shown in equation 7 below:

$$Vbody = Vtx * \frac{TX Cret}{TX Cret + Cbody} \qquad Equation 7$$

As the body capacitance is typically much larger than the transmitter capacitance, the body voltage is significantly reduced in this case. Similarly, for the receiver, if it is ground-connected, the received voltage equals the body voltage. If the receiver is ground-floated, the received voltage is further reduced based on the impedance relationships among the parasitic capacitances and load impedance. To maximize received power, the load resistance should be impedance-matched based on the receiver configuration. If the receiver is ground-connected, the load resistance should match the impedance of the body impedance and contact impedance. If the receiver is ground floated, then in equation 8:

$$Vrx = Vbody * \frac{Z x}{Z x + Zcret} \qquad Equation 8$$

Zcret refers to the AC impedance of the Cret. Zx refers to the combined parallel impedance of Cpp and Rload.

The system 700 supports bidirectional power transfer, allowing devices to act as both transmitters and receivers. This enables power sharing between devices, such as a phone transmitting power to a smartwatch, which in turn powers an electrocardiogram sensor. The electro-quasistatic human body powering system facilitates interconnected wearable ecosystems, reducing dependency on traditional batteries. By minimizing electromagnetic radiation, the system 700 improves energy efficiency and reduces interference with other systems, allowing independent operation of multiple electro-quasistatic human body powering setups on different individuals. Its adaptable design supports various device form factors, making it suitable for diverse applications. The system 700 sets a new standard for wireless power transfer, offering a scalable, efficient, and reliable solution for powering on-body electronic devices.

FIG. 10B illustrates a schematic diagram of simulation results torso cross-sectional areas 1000B without limb, according to an example embodiment of the present disclosure.

For example, modeling the body as R_{body}+Z_{contact} may not provide how body potential vary at different points when a small R_{load} is attached. Two trends observed from earlier in-vivo experiments and FEM based torso and limb simulations offer insight. When a small R_{load} is attached to the torso, on-body voltage generally recovers to levels similar to those before the load point, as shown in FIGS. 8A and 8C. However, in similar simulations on a limb, on-body voltage does not fully recover to before the load point levels, as shown in graph 1000G of FIG. 10G. This suggests that the torso and limbs behave differently under load, and this section presents FEM simulations to demonstrate that this difference arises from variations in cross-sectional area.

The FEM simulations 1000B and 1000C are shown in FIGS. 10B and 10C. The bottom of the body block connects to a ground-connected TX, outputting a 1 MHz, 1 Vpk signal, and a 1002 load with a 1 cm×1 cm contact area attaches to the body. Three primary simulations were conducted. (I) The model consists of only the torso with three different cross-sectional areas, with the load point located at the midpoint along the torso length to observe voltage recovery beyond the load point. (II) The model includes one limb and the torso, with the load applied at the limb. Here, the torso has three different cross-sectional areas to examine how the torso cross-sectional area affects voltage recovery on the limb. (III) The model also includes a limb and the torso, with the load attached to the limb. This time, the limb has three different cross-sectional areas to assess voltage recovery within the limb. FIG. 10B depicts the setup for simulation (I), while FIG. 10C shows the setups for simulations (II) and (III).

In graph 1000D in FIG. 10D, we observe that as the torso cross-sectional area decreases, the ability of the torso to recover on-body voltage after the small R_{load} load point diminishes. With a torso cross-sectional area of 100 cm², the on-body voltage nearly returns to the transmitted voltage (Vₜₓ), and the body behaves as an equipotential surface, except at the load point. Conversely, with a torso cross-sectional area of, the on-body voltage does not recover after the small R_{load}, causing the body to behave as if shorted to ground at the load point. This behavior is similarly observed in FIG. 10G in the presence of a limb. When the limb cross-sectional area is large (>100 cm²), the on-body voltage recovers after the small R_{load}. However, when the limb cross-sectional area is small, the on-body voltage fails to recover after the load point.

Further, the graph diagram 1000E in FIG. 10E serves as a reference. With one limb and a fixed cross-sectional area, varying the torso cross-sectional area does not change the on-body voltage recovery on the limb; it only changes the general on-body voltage, as the general R_{body} changes with the torso cross-sectional area. Additionally, the degree of on-body recovery depends on the R_{load} as well. As shown in FIG. 10F, at the same distance from the point of load, if the R_{load} is higher, the on-body voltage recovers more. When R_{load} is attached to the body, the degree of on-body voltage recovery after the load point depends on both the cross-sectional area of the body region and the R_{load}. As either the cross-sectional area or the R_{load} decreases, the on-body voltage recovery after the load point is reduced. Since capacitive EQS-HBP aims to maximize Pᵣₓ, Rload should be impedance matched to R_{body}+Z_{contact}. Given that typical human limb cross-sectional areas are in the order of tens of cm², careful placement of on-body RXs is essential to minimize the negative impact of reduced on-body voltage recovery. For instance, if multiple power RXs are placed on the body, higher total power can be achieved by avoiding placement exclusively on the limbs, as limbs generally have a smaller cross-sectional area than the torso. Additionally, if two power RXs are placed on the same limb, the RX closer to the torso should be designed to avoid significantly reducing the power available to the second RX by balancing its power draw.

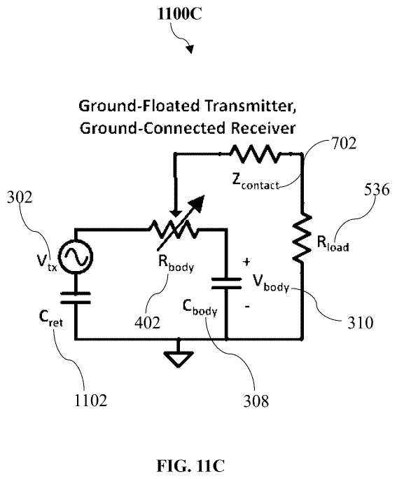

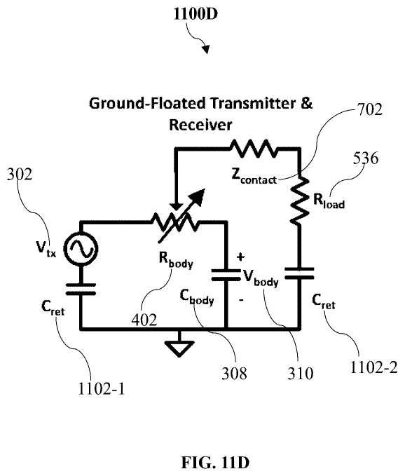

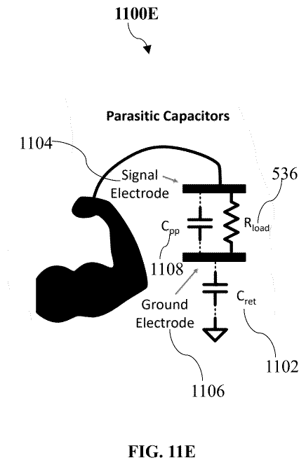

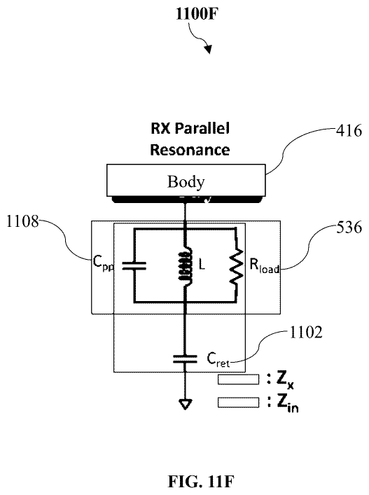

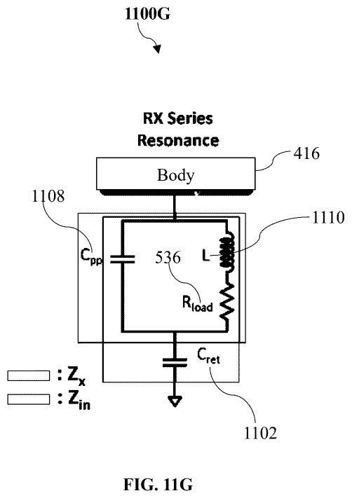

FIGS. 11A-D illustrates circuit diagrams of four configurations of capacitive EQS-HBP 1100A, 1100B, 1100C and 1100D, according to an example embodiment of the present disclosure.

Optimizing the Pᵣₓ in capacitive EQS-HBP is multi-faceted. This includes channel modeling, device optimization, and even environment modeling and optimization. After modeling the body with R_{body}+Z_{contact}, this section investigates circuit optimization to boost Pᵣₓ. Capacitive EQS-HBP can occur in four distinct configurations based on the ground-connectedness, as illustrated in FIGS. 11A-D. This ground-connectedness is sometimes also referred to as machine or wearable, in which ground-connected devices are considered as a machine as it is plugged into the electrical outlet and connected to the environmental ground, and ground-floated devices are considered as wearables where the ground electrode is left floating.

When the TX or RX is ground-floated, the device ground is not physically connected to the environmental ground but weakly coupled to it through Cᵣₑₜ. In addition to Cᵣₑₜ, another parasitic capacitance named Cₚₚ also critically affects the performance as it shunts current away from R_{load}. Cₚₚ is the parasitic capacitance between the signal and ground electrode and can be boosted from an effect known as body shadowing. To intuitively visualize Cᵣₑₜ and Cₚₚ, they are shown in circuit 1100E of FIG. 11E.

As Cᵣₑₜ limits the effective device current into and out of the body, it attenuates the power transmitted and received. To counteract the effect of it, inductive elements could be introduced to produce opposing reactive impacts. Conventional system includes two kinds of resonance such as parallel and series. For parallel resonance, an inductor is added between the TX ground and signal electrode. At resonance, this inductor resonates with Cₚₚ to reduce the shunt current through Cₚₚ and increase the powering efficiency. For series resonance, an inductor is added between the TX signal electrode and the body. At resonance, this inductor resonates with Cₚₚ and Cᵣₑₜ to boost on-body voltage at the expense of more shunt current. However, the exact cancellation of Cᵣₑₜ remains unexplored.

Despite a lack of prior examples of RX optimization for capacitive EQS-HBP, RX parallel resonance in circuit 1100F (FIG. 11F) has been demonstrated to boost the Pᵣₓ beyond the EQS frequency range. This technique could also be used for capacitive EQS-HBP but has yet to be thoroughly investigated. Furthermore, similar to TX, RX series resonance in circuit 1100G (FIG. 11G) is also possible. Hitherto, an in-depth analysis of the optimal resonance technique for capacitive EQS-HBP remains lacking and the following subsection aims to bridge this gap. In addition, since resonance is employed, the following section will also investigate the effect of the inductor Q factor on Pᵣₓ.

Lastly, since the resonance occurs between the inserted inductor and the TX and RX parasitic capacitance, rather than involving R_{body}+Z_{contact}, the circuit analysis will first focus on the TX and RX circuits individually for a simpler analysis. The impact of R_{body}+Z_{contact} act will be assessed after.

With the biophysical circuit model and series resonance technique established in previous sections, this subsection investigates the optimal R_{load} for maximizing Pᵣₓ across different configurations of capacitive EQS-HBP. The four configurations can be effectively reduced to two primary cases: RX as either ground-floated or ground-connected, with TX ground-connected in both scenarios. As demonstrated earlier, resonance does not mitigate the effect of Cᵣₑₜ for a ground-floated TX. Consequently, the on-body voltage at the ground-floated TX contact point is determined solely by the ratio of C_{ret TX} to C_{body} and remains unaffected by R_{body}, Z_{contact}, or the RX ground connection. Thus, the ground-floated TX can be modeled as a ground-connected TX with a reduced Vₜₓ. Although ground-connected TX Z_{contact} could vary V_{body} with different RX Zᵢₙ, ground-connected TX generally have much more relaxed sizing constraints compared to RX, leading to Z_{contact TX}<<R_{body}, reducing the importance of this issue. Thus, we approximate Z_{contact} TX as negligible.

For the configuration where both TX and RX are ground-connected, Pᵣₓ can be approximated as shown in equation 9 below:

$$P r x = \frac{1}{{R}_{load}} {( {V}_{tx} \frac{{R}_{l o a d}}{{R}_{load} + {R}_{body} + {Z}_{contact}} )}^{2} \qquad Equation 9$$

In equation 9, maximum Pᵣₓ is achieved when R_{load}=R_{body}+Z_{contact}. Additionally, Pᵣₓ is inversely proportional to R_{body}+Z_{contact}, highlighting the importance of minimizing Z_{contact} to enhance Pᵣₓ. In the configuration where the RX is ground-floated and the TX is ground-connected with series resonance, resonance alignment and inductor Q factor significantly influence optimal R_{load}. When the RX resonant frequency aligns perfectly with the TX frequency, and the inductor Q factor is high with a large

$$\frac{{C}_{ret}}{{C}_{pp}}$$

ratio, Cᵣₑₜ can be effectively canceled, enabling Zᵢₙ≈R_{load}. This transforms the ground-floated RX into a ground-connected configuration.

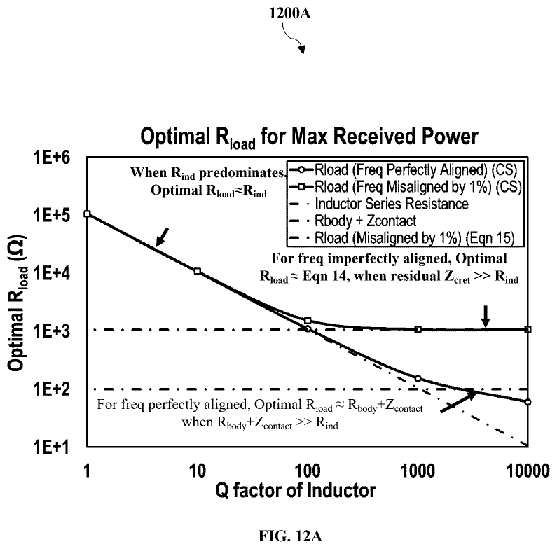

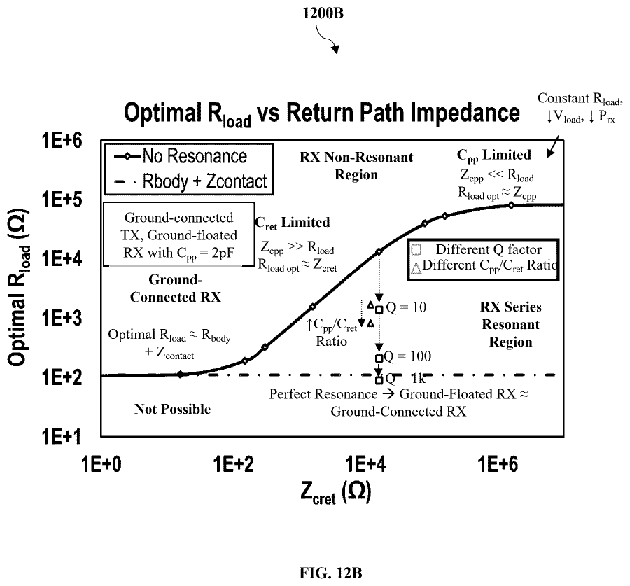

FIG. 12A illustrates a graph diagram 1200A of an optimal Rload that maximizes Prx across two scenarios such as perfect and imperfect frequency alignment between TX and RX series resonance frequency, according to an example embodiment of the present disclosure. FIG. 12B illustrates a graph diagram 1200B of an optimal Rload that maximizes Prx across different return path impedance, covering from ground-connected RX to ground-floated RX, according to an example embodiment of the present disclosure.

As shown in equation 9, peak Pᵣₓ occurs when R_{load}=R_{body}+Z_{contact}, illustrated by the red curve in FIG. 12A with an idealized Q factor approaching infinity.

However, when the inductor Q factor is low, as detailed in the previous subsection, the non-ideal inductor can be modeled as a perfect inductor in series with R_{ind}. While the ideal inductor cancels Z_{C}_{ᵣₑₜ}, the RX Zᵢₙ becomes R_{ind}+R_{load}. If R_{ind}>>R_{body}+Z_{contact}, then Zᵢₙ>>R_{body}+Z_{contact}, and peak Pᵣₓ occurs when R_{load} matches R_{ind}, as shown in FIG. 12A for low Q factor regions. Practical misalignment between TX and RX frequencies further complicates performance. Minor frequency mismatches lead to incomplete cancellation of Cᵣₑₜ, and as the Q factor of a misaligned RX approaches infinity, RX Zᵢₙ=R_{load}+Z_{C}_{_{ret residual}}. Since Z C_{ret residual}>>R_{body}+Z_{contact} due to the small capacitance of Cᵣₑₜ, peak Pᵣₓ occurs when R_{load} matches Z_{C}_{_{ret residual}}, calculable using parameters k₄-k₅ with equations:

$${R}_{loadopt}^{2} \approx \frac{{k}_{3} {k}_{5} - 3 {k}_{2} {k}_{4} - \sqrt{{( 3 {k}_{2} {k}_{4} - {k}_{3} {k}_{5} )}^{2} - 4 {k}_{2} {k}_{3} {k}_{4} {k}_{5}}}{2 {k}_{2} {k}_{5}} \qquad Equation 10$$

In summary, the optimal R_{load} for a ground-floated RX with series resonance can be expressed as:

$${R}_{loadopt} = max ( {R}_{ind} , {R}_{body} + {Z}_{c o n t a c t} , {Z}_{{C}_{retresidual}} ) \qquad Equation 11$$

In the absence of resonance, Pᵣₓ can be approximated as:

$${P}_{rx} = \frac{1}{{Z}_{l o a d}} \cdot {( {V}_{tx} \cdot \frac{{Z}_{l o a d}}{{Z}_{l o a d} + {R}_{body} + {Z}_{contact} + {Z}_{{C}_{r e t}}} )}^{2} \qquad Equation 12$$

As Z_{C}_{ᵣₑₜ}>>R_{body}+Z_{contact}, the denominator can be simplified to Z_{load}+Z_{C}_{ᵣₑₜ}, where Z_{load}=Z_{C}_{ₚₚ}∥R_{load}. When Z_{C}_{ᵣₑₜ}<<Z_{C}_{ₚₚ}, peak Pᵣₓ occurs at R_{load}≈Z_{C}_{ᵣₑₜ} as Z_{C}_{ₚₚ} can be disregarded, shown in FIG. 12B in the Cᵣₑₜ-limited region. In contrast, when Z_{C}_{ᵣₑₜ}>>Z_{C}_{ₚₚ}, the peak Pᵣₓ occurs at R_{load}≈Z_{C}_{ₚₚ} as V_{load} saturates with further R_{load} increment, shown in FIG. 12B Cₚₚ-limited region.

In summary, FIG. 12B provides a comprehensive plot of this analysis. RX series resonance reduces the optimal R_{load}, with the extent of reduction primarily influenced by the inductor Q factor and the ratio of Cᵣₑₜ to Cₚₚ. Given that the ratio of Cᵣₑₜ to Cₚₚ varies less significantly than the inductor Q factor, optimizing the inductor Q factor is more critical. Additionally, R_{body}+Z_{contact} sets a lower limit on the optimal R_{load}, highlighting the importance of minimizing Z_{contact}, as a lower optimal R_{load} typically leads to an increase in Pᵣₓ.

Finally, while equation 11 approximates R_{load} accurately in regions with clear maxima, it may not precisely predict R_{load} near the intersection of R_{ind} with either R_{body}+Z_{contact} or Z_{C}_{_{ret residual}}. Further research is needed to refine this. In practical applications, human motion introduces fluctuations in Cᵣₑₜ and Cₚₚ, necessitating dynamic adjustments to the TX or RX resonant frequency to mitigate frequency misalignment and adjustments to R_{load} in response to these variations. This subsection, therefore, establishes approximate values and bounds for optimal R_{load}, providing a foundation for designing such an adaptive algorithm.

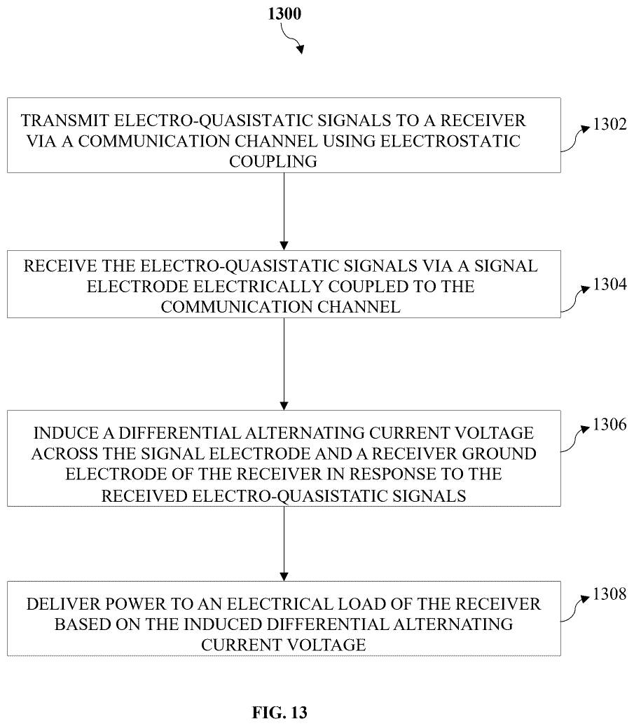

FIG. 13 illustrates an exemplary flow chart depicting a method 1300 for powering devices utilizing Human Whole-Body Powering (HWBP) via capacitive electro-quasistatic fields, according to an example embodiment of the present disclosure. At step 1302, the method 1300 includes transmitting, by the system 100A via the transmitter 102, electro-quasistatic signals to a receiver via a human body channel using electrostatic coupling. The electro-quasistatic signals power the receiver, and the human body channel comprises a body impedance value, a capacitive coupling, and a contact impedance. The human body channel is configured to transfer the electro-quasistatic signals from the transmitter to the receiver.

At step 1304, the method 1300 includes receiving, by the system 100A via the receiver 104, the electro-quasistatic signals via a signal electrode electrically coupled to the human body channel.

At step 1306, the method 1300 includes inducing, by the system 100A via the receiver 104, a differential alternating current voltage across the signal electrode and a receiver ground electrode of the receiver in response to the received electro-quasistatic signals. The differential alternating current voltage comprises a frequency corresponding to frequency of the electro-quasistatic signals and an amplitude dependent on a grounding configuration of the transmitter and the receiver.

At step 1308, the method 1300 includes delivering, by the system 100A via the receiver 104, power to an electrical load of the receiver based on the induced differential alternating current voltage.

The method 1300 may be implemented in any suitable hardware, software, firmware, or combination thereof. The order in which the method 1300 is described is not intended to be construed as a limitation, and any number of the described method blocks may be combined or otherwise performed in any order to implement the method 1300 or an alternate method. Additionally, individual blocks may be deleted from the method 1300 without departing from the spirit and scope of the present disclosure described herein. Furthermore, the method 1300 may be implemented in any suitable hardware, software, firmware, or a combination thereof, that exists in the related art or that is later developed. The method 1300 describes, without limitation, the implementation of the system 100A-B. A person of skill in the art will understand that method 1300 may be modified appropriately for implementation in various manners without departing from the scope and spirit of the disclosure.

The system may be a hardware device including the hardware processor executing machine-readable program instructions for converting the direct analog samples to compressed digitized samples. Execution of the machine-readable program instructions by the hardware processor may enable the system 100A-B to convert the direct analog samples to compressed digitized samples. The “hardware” may comprise a combination of discrete components, an integrated circuit, an application-specific integrated circuit, a field-programmable gate array, a digital signal processor, or other suitable hardware. The “software” may comprise one or more objects, agents, threads, lines of code, subroutines, separate software applications, two or more lines of code, or other suitable software structures operating in one or more software applications or on one or more processors.

The hardware processor(s) may include, but are not limited to, microprocessors, microcomputers, microcontrollers, digital signal processors, central processing units, state machines, logic circuits, and/or any devices that manipulate data or signals based on operational instructions, and the like. Among other capabilities, hardware processor may fetch and execute computer-readable instructions in the memory operationally coupled with the system 100A-B for performing tasks such as data processing, input/output processing, and/or any other functions. Any reference to a task in the present disclosure may refer to an operation being or that may be performed on data.

Embodiments herein provide a powering system and a method for powering devices utilizing Human Whole-Body Powering (HWBP) via capacitive electro-quasistatic fields. The present disclosure provides several advantages in the field of wireless power transfer within Body Area Networks (BANs) by utilizing capacitive human body powering (HBP) in the electro-quasistatic (EQS) frequency range. Embodiments herein utilizes the human body as a medium for power transfer between on-body devices, addressing critical limitations of conventional power delivery systems. By operating within the EQS frequency range below 30 MHz, the system significantly reduces electromagnetic radiation. This reduction not only enhances signal containment but also minimizes interference with external electronic systems, allowing multiple independent EQS-HBP systems to operate on different individuals without mutual disruption. Furthermore, the low electromagnetic radiation ensures compliance with safety standards while maintaining efficient power delivery across the human body.

A key advantage of the system lies in its ability to deliver continuous and reliable power without relying on conventional battery-based solutions. Traditional power sources, such as lithium-polymer batteries, are often constrained by limited energy storage capacity, necessitating frequent recharging and contributing to increased device size. In contrast, the capacitive EQS-HBP system enables a consistent power supply by exploiting the human body's inherent electrical properties. This ensures a scalable and efficient power transfer mechanism capable of supporting diverse wearable devices, ranging from smartwatches and medical sensors to advanced diagnostic equipment. The system's design supports both ground-floated and ground-connected configurations, offering enhanced implementation flexibility across various device architectures and operational environments.

The system also supports bidirectional power transfer, enabling dynamic energy sharing between interconnected devices. This capability is particularly advantageous for wearable ecosystems, where one device, such as a smartphone, can wirelessly transfer power to secondary devices like smartwatches or medical sensors. Such a configuration reduces the reliance on individual power sources for each device, fostering a more integrated and autonomous operational framework. The bidirectional nature of the power transfer extends the functionality and longevity of on-body devices, allowing continuous monitoring and communication without the need for frequent battery replacements or manual charging.

Moreover, simplified circuit design of the EQS-HBP system reduces the complexity and cost of implementation while maintaining high energy transfer efficiency. Through circuit optimization techniques, including the application of series resonance cancellation at the receiver, the system enhances power reception without increasing the complexity of the transmitter. This optimization is further supported by approximations for the optimal load resistance, ensuring that the power received by the load is maximized under practical operating conditions. These design considerations contribute to the overall efficiency, reliability, and scalability of the system across various biomedical and consumer applications.

The capacitive EQS-HBP system circumvents technical challenges of conventional systems by providing whole-body coverage exceeding one meter, enabling seamless power delivery across multiple devices situated on the human body. This comprehensive and innovative approach to wireless power transfer offers a highly adaptable, energy-efficient, and reliable solution, setting a new standard for powering on-body electronic devices across diverse applications.

While both EQS-HBC and EQS-HBP share operational similarities, optimization goals of the EQS-HBC and EQS-HBP differ. EQS-HBC prioritizes enhancing communication channel capacity, whereas EQS-HBP aims to maximize received power (Prx) through impedance matching method. Furthermore, EQS-HBP operates in two modes such as capacitive and galvanic, with capacitive EQS-HBP offering superior full-body coverage, making it a more effective solution for powering on-body devices.

Electro-quasistatic human body communication (EQS-HBC) was initially developed as a low-energy, high-bandwidth solution for near-body communication before being adapted for human-body powering (EQS-HBP). HBC is a data communication technique with two operational modes such as capacitive and galvanic. Among these, capacitive EQS-HBC offers superior full-body coverage, making it suitable for wireless power transfer through the human body. In the proposed system, a wearable transmitter (TX) and receiver (RX) are connected to the body via their signal electrodes, while their ground electrodes remain floating. The TX transmits an alternating current (AC) signal through body tissues to the RX. The return path for the signal is established through the RX floating ground, the environmental Earth ground, and the TX floating ground. This return path relies on parasitic capacitances between the floating grounds of the devices and the environmental Earth ground, which defines the technique as capacitive EQS-HBP. This approach uses the electro-quasistatic properties of the body to enable efficient power transfer while maintaining minimal energy consumption.

One of the ordinary skilled in the art will appreciate that techniques consistent with the present disclosure are applicable in other contexts as well without departing from the scope of the disclosure.

What has been described and illustrated herein are examples of the present disclosure. The terms, descriptions, and figures used herein are set forth by way of illustration only and are not meant as limitations. Many variations are possible within the spirit and scope of the subject matter, which is intended to be defined by the following claims and their equivalents in which all terms are meant in their broadest reasonable sense unless otherwise indicated.

The written description describes the subject matter herein to enable any person skilled in the art to make and use the embodiments. The scope of the subject matter embodiments is defined by the claims and may include other modifications that occur to those skilled in the art. Such other modifications are intended to be within the scope of the claims if they have similar elements that do not differ from the literal language of the claims or if they include equivalent elements with insubstantial differences from the literal language of the claims.

The embodiments herein can comprise hardware and software elements. The embodiments that are implemented in software include but are not limited to, firmware, resident software, microcode, a. The functions performed by various modules described herein may be implemented in other modules or combinations of other modules. For the purposes of this description, a computer-usable or computer-readable medium can be any apparatus that can comprise, store, communicate, propagate, or transport the program for use by or in connection with the instruction execution system, apparatus, or device.

A description of an embodiment with several components in communication with each other does not imply that all such components are required. On the contrary, a variety of optional components are described to illustrate the wide variety of possible embodiments of the invention. When a single device or article is described herein, it will be apparent that more than one device/article (whether or not they cooperate) may be used in place of a single device/article. Similarly, where more than one device or article is described herein (whether or not they cooperate), it will be apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments of the invention need not include the device itself.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, and the like, of those described herein) will be apparent to persons skilled in the relevant art(s) based on the teachings contained herein. Such alternatives fall within the scope and spirit of the disclosed embodiments. Also, the words “comprising,” “having,” “containing,” and “including,” and other similar forms are intended to be equivalent in meaning and be open-ended in that an item or items following any one of these words is not meant to be an exhaustive listing of such item or items or meant to be limited to only the listed item or items. It must also be noted that as used herein and in the appended claims, the singular forms “a”, “an”, and “the” include plural references unless the context clearly dictates otherwise.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limited, of the scope of the invention, which is outlined in the following claims.

What is claimed is:

1. A powering system for powering devices utilizing a Human Whole-Body Powering (HWBP) via capacitive electro-quasistatic fields, the powering system comprising:
a transmitter configured to:
transmit electro quasistatic signals to a receiver via a human body channel using an electrostatic coupling, wherein the electro quasistatic signals are configured to power the receiver;
a human body electrically connected to the transmitter, wherein the human body channel is configured to:
transfer the electro quasistatic signals from the transmitter to the receiver, and wherein the human body channel comprises a body impedance value, a capacitive coupling, a contact impedance; and
the receiver electrically connected to the human body channel, wherein the receiver is configured to:
deliver power to an electrical load of the receiver based on a powering level.

2. The powering system of claim 1, wherein the transmitter and the receiver comprise a signal electrode connected to the human body channel.

3. The powering system of claim 1, wherein the body impedance value represents an impedance of the human body channel, and wherein the contact impedance represents an impedance at an interface between a signal electrode and the human body channel, and wherein the transmitter and receiver comprises a parasitic capacitance Cᵣₑₜ represents a capacitance between the human body channel and an environmental ground and a parasitic capacitance Cₚₚ between the signal electrode and a ground electrode, wherein the contact impedance comprises a magnitude value being inversely proportional to a contact area size.

4. The powering system of claim 3, wherein the body impedance value is determined using a height of a human body, a cross-sectional area of the human body and a muscle conductivity.

5. The powering system of claim 1, wherein the transmitter comprises a ground-connected configuration, wherein the ground-connected configuration comprises a ground electrode of the transmitter connected in at least two configurations, wherein the at least two configurations comprises the ground electrode electrically connected to an environmental ground and, wherein the at least two configurations comprises the ground electrode in close proximity to the environmental ground.

6. The powering system of claim 1, wherein the receiver comprises a ground-connected configuration, wherein the ground-connected configuration comprises a ground electrode of the receiver connected in at least two configurations, wherein the at least two configurations comprises the ground electrode electrically connected to an environmental ground, and wherein the at least two configurations comprises the ground electrode in close proximity to the environmental ground.

7. The powering system of claim 1, wherein the transmitter comprises a ground-floated configuration, wherein the ground-floated configuration comprises a floating ground electrode of the transmitter being isolated from an environmental ground.

8. The powering system of claim 1, wherein the receiver comprises a ground-floated configuration, wherein the ground-floated configuration comprises a floating ground electrode of the receiver being isolated from the environmental ground.

9. The powering system of claim 1, wherein the transmitter comprises a ground electrode of a size configurable based on a device form factor, and the receiver comprises a ground electrode of a size configurable based on a device form factor.

10. The powering system of claim 6, wherein in the ground-connected configuration, the transmitter is electrically connected to the environmental ground and a voltage of the human body channel corresponds to a complete electro-quasistatic alternating current voltage of the transmitter.

11. The powering system of claim 7, wherein in the ground-floated configuration, the transmitter is electrically isolated from the environmental ground and a voltage of the human body channel is determined based on a ratio of Body-to-environmental ground parasitic capacitance (C_{body}) and a parasitic capacitance formed between the ground electrode of the transmitter and the environmental ground (Cᵣₑₜ).

12. The powering system of claim 1, wherein to deliver the power to the electrical load of the receiver based on the powering level, the receiver is configured to:
determine if the receiver is in ground-floated configuration and if a parasitic capacitance between the received signal and a ground electrode of the receiver (Cₚₚ) is larger than a parasitic capacitance formed between the ground electrode of the receiver and an environmental ground (Cᵣₑₜ);
configure a load resistance value of the electrical load to be impedance-matched to the parasitic capacitance between the received signal and the ground electrode of the receiver (Cₚₚ); and
deliver power to the electrical load of the receiver based on the configured load resistance value.

13. The powering system of claim 1, wherein to power the power unit of the receiver upon receiving the electro quasistatic signals, the receiver is configured to:
determine if the receiver is in ground-floated configuration and if a parasitic capacitance between a received signal and a ground electrode of a receiver Cₚₚ value is lesser than the parasitic capacitance formed between the ground electrode of the receiver and an environmental ground (Cᵣₑₜ);
configure a load resistance value of the electrical load to be impedance-matched to the parasitic capacitance formed between the ground electrode of the receiver and the environmental ground (Cᵣₑₜ); and
deliver power to the electrical load of the receiver based on the configured load resistance value.

14. The powering system of claim 1, wherein to deliver power to the power unit of the receiver upon receiving the electro quasistatic signals, the receiver is configured to:
determine if the receiver is in ground-connected configuration;
match a load resistance value of the electrical load with an impedance of the body impedance value and the contact impedance; and
deliver power to the electrical load of the receiver based on the matched load resistance value.

15. The powering system of claim 1, wherein the transmitter is configured to adjust a frequency of the transmitted electro quasistatic signals.

16. The powering system of claim 1, wherein the receiver is configured to:
deliver power using a differential alternating current voltage across a signal electrode and a ground electrode in response to the received electro quasistatic signals, wherein the differential alternating current voltage comprises a frequency corresponding to a frequency of the received electro-quasistatic signals and an amplitude dependent on a grounding configuration of the transmitter and the receiver.

17. The powering system of claim 16, wherein the receiver comprises the electrical load electrically connected to a signal electrode and the ground electrode of the receiver and wherein the electrical load is configured to extract power from the differential alternating current voltage.

18. The powering system of claim 1, wherein the transmitter is configured to transmit the electro quasistatic signals until a signal electrode of the transmitter remain in conductive contact with the human body channel.

19. The powering system of claim 1, wherein the powering system comprises one or more wearable devices comprising a first transceiver and a central system comprising a second transceiver, wherein the first transceiver and the second transceiver alternately operate as the transmitter and as the receiver to transfer bi-directional power between the first transceiver and the second transceiver.

20. A method for powering devices utilizing Human Whole-Body Powering (HWBP) via capacitive electro-quasistatic fields, the method comprising:
transmitting, by a transmitter, electro quasistatic signals to a receiver via a human body channel using electrostatic coupling, wherein the electro-quasistatic signals power the receiver, and wherein the human body channel comprises a body impedance value, a capacitive coupling, and a contact impedance, and wherein the human body channel is configured to transfer the electro-quasistatic signals from the transmitter to the receiver;
receiving, by the receiver, the electro quasistatic signals via a signal electrode electrically coupled to the human body channel;
inducing, by the receiver, a differential alternating current voltage across the signal electrode and a receiver ground electrode of the receiver in response to the received electro quasistatic signals, wherein the differential alternating current voltage comprises a frequency corresponding to frequency of the electro quasistatic signals and an amplitude dependent on a grounding configuration of the transmitter and the receiver; and
deliver, by the receiver, power to an electrical load of the receiver based on the induced differential alternating current voltage.
